(19) United States
(12) Patent Application Publication
(10) Pub. No.: US 2025/0118893 A1
(43) Pub. Date: Apr. 10, 2025

(54) ELECTRONIC DEVICE COMPRISING ANTENNA

(71) Applicant: Samsung Electronics Co., Ltd., Suwon-si (KR)

(72) Inventors: Pilwon SEO, Suwon-si (KR); Seonguk PARK, Suwon-si (KR); Seokwoo LEE, Suwon-si (KR); Junhee HAN, Suwon-si (KR); Jiyoung KIM, Suwon-si (KR); Jeongseob KIM, Suwon-si (KR)

(21) Appl. No.: 18/982,370

(22) Filed: Dec. 16, 2024

Related U.S. Application Data
(63) Continuation of application No. PCT/KR2023/008548, filed on Jun. 20, 2023.

(30) Foreign Application Priority Data
Jun. 20, 2022 (KR) 10-2022-0075140
Aug. 4, 2022 (KR) 10-2022-0097440

(51) Int. Cl. H01Q 3/02; G06F 1/16; H01Q 1/24

(52) U.S. Cl. CPC H01Q 3/02; H01Q 1/243; G06F 1/1641

(57) ABSTRACT

An electronic is provided. The electronic device includes a first housing, a second housing rotatably connected to the first housing, a display disposed on the front surface of the electronic device and having a partial area configured to be deformed by a rotation of the second housing relative to the first housing, a first antenna module disposed on one of the first housing and the second housing so that a communication signal is radiated in a direction identical to a direction in which the display faces the outside of the electronic device, and a radiation part included in the other or the first housing and the second housing and including an internal space that faces the first antenna module in a state in which the electronic device is folded so that the first housing and the second housing face each other, wherein the first antenna module transmits or receives the communication signal in a designated frequency band through the radiation part.

### CROSS-REFERENCE TO RELATED APPLICATION(S)

This application is a continuation application, claiming priority under § 365 (c), of an International application No. PCT/KR2023/008548, filed on Jun. 20, 2023, which is based on and claims the benefit of a Korean patent application number 10-2022-0075140, filed on Jun. 20, 2022, in the Korean Intellectual Property Office, and of a Korean patent application number 10-2022-0097440, filed on Aug. 4, 2022, in the Korean Intellectual Property Office, the disclosure of each of which is incorporated by reference herein in its entirety.

### BACKGROUND

### 1. Field

The disclosure relates to an electronic device including an antenna.

### 2. Description of Related Art

With the development of wireless communication technology, electronic devices (e.g., an electronic device for communication) are widely used in daily life, and thus the use of contents is increasing. Due to the rapid increase in the use of contents, the network capacity is gradually reaching the limit. After the commercialization of 4th-generation (4G) communication systems, communication systems (e.g., a 5th-generation (5G) communication system, a pre-5G communication system, or a new radio (NR) communication system), which transmit or receive signals by using a high-frequency (e.g., millimeter-wave (mmWave)) band (e.g., 3 GHZ to 300 GHz band), is studied to satisfy the increasing demands for radio data traffic.

The above information is presented as background information only to assist with an understanding of the disclosure. No determination has been made, and no assertion is made, as to whether any of the above might be applicable as prior art with regard to the disclosure.

### SUMMARY

An electronic device may operate in such a way that two housings are folded or unfolded about a folding axis.

The electronic device may be equipped with an antenna module that may transmit or receive a communication signal in an mmWave band (e.g., a frequency band in about 3 GHz to 100 GHz range). The antenna module may be disposed in any one housing so that a beam pattern is formed in a particular direction in the electronic device.

Meanwhile, in case that the two housings are folded about the folding axis, the antenna module disposed in any one housing may face an electric component or a metal member disposed in the other housing. In this case, radiation performance of the antenna module may be degraded.

Aspects of the disclosure are to address at least the above-mentioned problems and/or disadvantages and to provide at least the advantages described below. Accordingly, an aspect of the disclosure is to provide an electronic device capable of mitigating or suppressing degradation of radiation performance of the antenna module in a state in which the electronic device is folded.

Additional aspects will be set forth in part in the description which follows and, in part, will be apparent from the description, or may be learned by practice of the presented embodiments.

In accordance with an aspect of the disclosure, an electronic device is provided. The electronic device includes a first housing, a second housing rotatably connected to the first housing, a display disposed on a front surface of the electronic device and having a partial area configured to be deformed by a rotation of the second housing relative to the first housing, a first antenna module disposed on one of the first housing and the second housing so that a communication signal is radiated in a direction identical to a direction in which the display faces the outside of the electronic device, and a radiation part included in the other of the first housing and the second housing and including an internal space that faces the first antenna module in a state in which the electronic device is folded so that the first housing and the second housing face each other, wherein the first antenna module transmits or receives the communication signal in a designated frequency band through the radiation part.

In accordance with another aspect of the disclosure, an electronic device is provided. The electronic device includes a first housing, a second housing rotatably connected to the first housing, a first display disposed on the first housing and the second housing so as to face a front surface of the electronic device and having a partial area configured to be deformed by a rotation of the second housing relative to the first housing, a second display disposed on one of the first housing and the second housing so as to be directed toward a rear surface of the electronic device, a first antenna module disposed on the second housing so that a communication signal is radiated in a direction identical to a direction in which the second display faces the outside of the electronic device, a second antenna module positioned toward a side surface that surrounds the front surface and the rear surface of the electronic device, the second antenna module being disposed on one of the first housing and the second housing, memory storing one or more computer programs, and one or more processors communicatively coupled to the first antenna module, the second antenna module, and the memory, wherein the one or more computer programs include computer-executable instructions that, when executed by the one or more processors individually or collectively, cause the electronic device to control communication signals of the first and second antenna modules on the basis of a rotated state of the first housing and a rotated state of the second housing.

According to various embodiments of the disclosure, the electronic device includes the radiation part formed in one area of the other housing facing the antenna module disposed in any one housing in the state in which the two housings are folded to face each other. In the state in which the electronic device is folded, the antenna module transmits or receive the communication signal through the radiation part. Therefore, it is possible to mitigate or eliminate the degradation of the radiation performance of the antenna module in the state in which the electronic device is folded.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following the description taken in conjunction with the accompanying drawings, in which:

FIG. 1 is a block diagram of an electronic device in a network environment 100 according to an embodiment of the disclosure;

FIG. 2 is a block diagram of the electronic device for supporting legacy network communication and 5G network communication according to an embodiment of the disclosure;

FIGS. 3A and 3B are views illustrating an unfolded state (unfolded stage) of the electronic device when viewed from front and rear surfaces thereof according to various embodiments of the disclosure;

FIGS. 4A and 4B are views illustrating a folded state of the electronic device when viewed from the front and rear surfaces thereof according to various embodiments of the disclosure;

FIG. 5 is an exploded perspective view of the electronic device according to an embodiment of the disclosure;

FIG. 6A is a view illustrating the front surface of the electronic device illustrated in FIGS. 3A, 3B, 4A, 4B, and 5 and a front surface of an electronic device when in the unfolded state according to an embodiment of the disclosure;

FIG. 6B is a view illustrating the rear surface of the electronic device illustrated in FIGS. 3A, 3B, 4A, 4B, and 5 and a rear surface of the electronic device when in the unfolded state according to an embodiment of the disclosure;

FIG. 7 is a view illustrating a structure of an antenna module according to an embodiment of the disclosure;

FIG. 8 is a cross-sectional view of the electronic device taken along line C-C in FIG. 6A according to an embodiment of the disclosure;

FIGS. 9A, 9B, and 9C are views illustrating states in which a first antenna module and a radiation part face each other in a state in which the electronic device illustrated in FIG. 8 is folded according to various embodiments of the disclosure;

FIG. 10 is a view illustrating a state in which a first housing and a second housing are asymmetrically folded about a folding axis in electronic device illustrated in FIGS. 9A, 9B and 9C according to an embodiment of the disclosure;

FIG. 11A is a view illustrating the rear surface of the electronic device in a state in which the electronic device illustrated in FIG. 6A and the electronic device are unfolded according to an embodiment of the disclosure;

FIG. 11B is a cross-sectional view of the electronic device taken along line D-D in FIG. 11A according to an embodiment of the disclosure; and

FIG. 11C is a view illustrating a state in which the electronic device in FIGS. 11A and 11B is folded according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a Wi-Fi chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

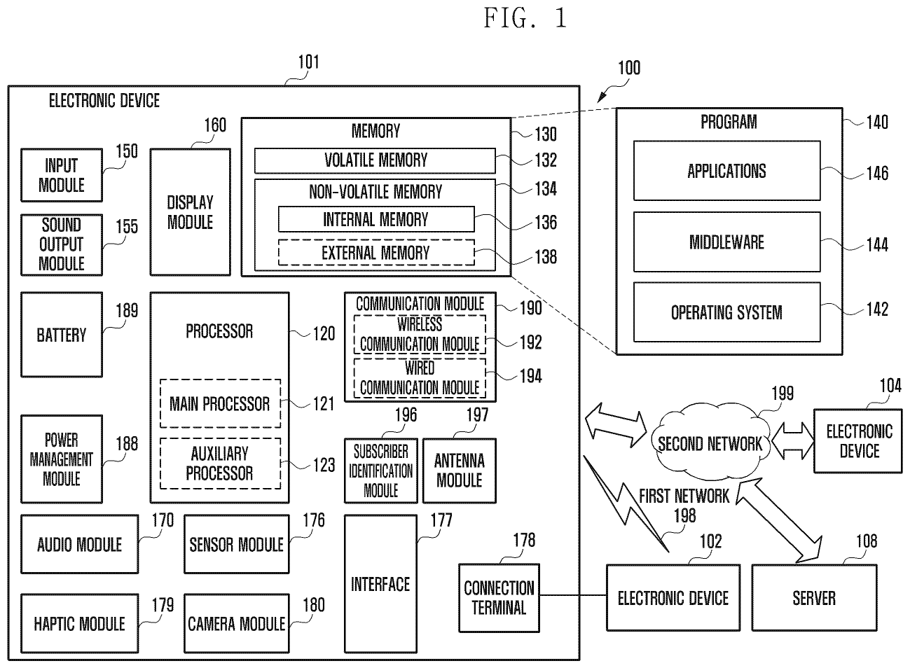

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

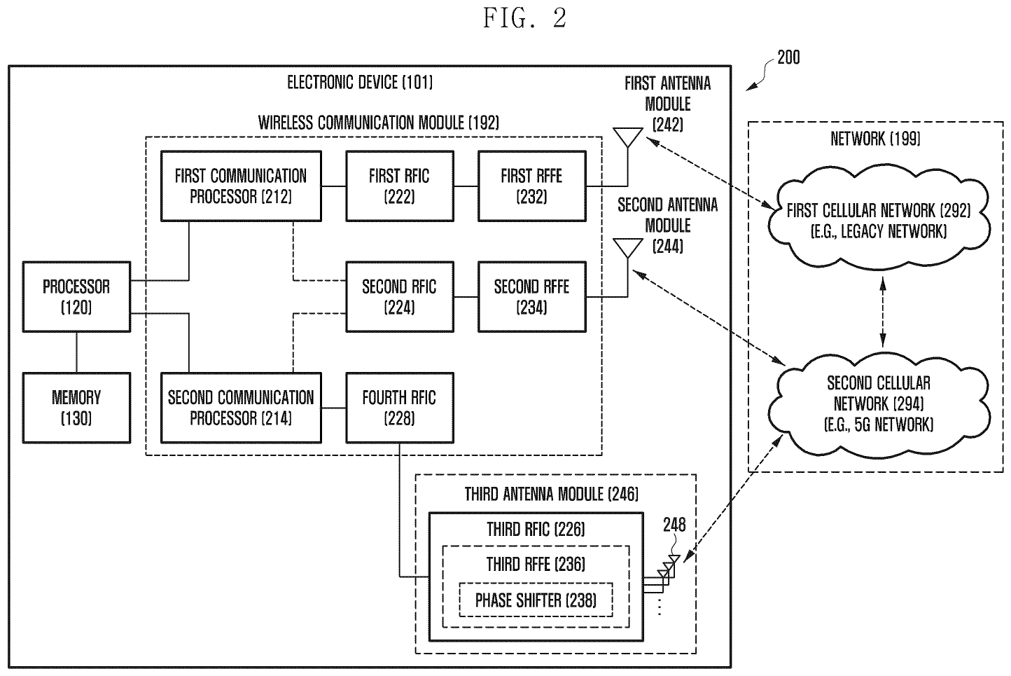

FIG. 2 is a block diagram illustrating an electronic device in a network environment 200 including a plurality of cellular networks according to an embodiment of the disclosure.

Referring to FIG. 2, the electronic device 101 may include a first communication processor 212, second communication processor 214, first RFIC 222, second RFIC 224, third RFIC 226, fourth RFIC 228, first radio frequency front end (RFFE) 232, second RFFE 234, first antenna module 242, second antenna module 244, and antenna 248. The electronic device 101 may include a processor 120 and memory 130. A second network 199 may include a first cellular network 292 and a second cellular network 294. According to another embodiment, the electronic device 101 may further include at least one of the components described with reference to FIG. 1, and the second network 199 may further include at least one other network. According to one embodiment, the first communication processor 212, second communication processor 214, first RFIC 222, second RFIC 224, fourth RFIC 228, first RFFE 232, and second RFFE 234 may form at least part of the wireless communication module 192. According to another embodiment, the fourth RFIC 228 may be omitted or included as part of the third RFIC 226.

The first communication processor 212 may establish a communication channel of a band to be used for wireless communication with the first cellular network 292 and support legacy network communication through the established communication channel. According to various embodiments, the first cellular network may be a legacy network including a second generation (2G), 3G, 4G, or long term evolution (LTE) network. The second communication processor 214 may establish a communication channel corresponding to a designated band (e.g., about 6 GHz to about 60 GHZ) of bands to be used for wireless communication with the second cellular network 294, and support 5G network communication through the established communication channel. According to various embodiments, the second cellular network 294 may be a 5G network defined in 3GPP. Additionally, according to an embodiment, the first communication processor 212 or the second communication processor 214 may establish a communication channel corresponding to another designated band (e.g., about 6 GHz or less) of bands to be used for wireless communication with the second cellular network 294 and support 5G network communication through the established communication channel. According to one embodiment, the first communication processor 212 and the second communication processor 214 may be implemented in a single chip or a single package. According to various embodiments, the first communication processor 212 or the second communication processor 214 may be formed in a single chip or a single package with the processor 120, the auxiliary processor 123, or the communication module 190.

Upon transmission, the first RFIC 222 may convert a baseband signal generated by the first communication processor 212 to a radio frequency (RF) signal of about 700 MHz to about 3 GHz used in the first cellular network 292 (e.g., legacy network). Upon reception, an RF signal may be obtained from the first cellular network 292 (e.g., legacy network) through an antenna (e.g., the first antenna module 242) and be preprocessed through an RFFE (e.g., the first RFFE 232). The first RFIC 222 may convert the preprocessed RF signal to a baseband signal so as to be processed by the first communication processor 212.

Upon transmission, the second RFIC 224 may convert a baseband signal generated by the first communication processor 212 or the second communication processor 214 to an RF signal (hereinafter, 5G Sub6 RF signal) of a Sub6 band (e.g., 6 GHz or less) to be used in the second cellular network 294 (e.g., 5G network). Upon reception, a 5G Sub6 RF signal may be obtained from the second cellular network 294 (e.g., 5G network) through an antenna (e.g., the second antenna module 244) and be pretreated through an RFFE (e.g., the second RFFE 234). The second RFIC 224 may convert the preprocessed 5G Sub6 RF signal to a baseband signal so as to be processed by a corresponding communication processor of the first communication processor 212 or the second communication processor 214.

The third RFIC 226 may convert a baseband signal generated by the second communication processor 214 to an RF signal (hereinafter, 5G Above6 RF signal) of a 5G Above6 band (e.g., about 6 GHz to about 60 GHZ) to be used in the second cellular network 294 (e.g., 5G network). Upon reception, a 5G Above6 RF signal may be obtained from the second cellular network 294 (e.g., 5G network) through an antenna (e.g., the antenna 248) and be preprocessed through the third RFFE 236. The third RFIC 226 may convert the preprocessed 5G Above6 RF signal to a baseband signal so as to be processed by the second communication processor 214. According to one embodiment, the third RFFE 236 may be formed as part of the third RFIC 226.

According to an embodiment, the electronic device 101 may include a fourth RFIC 228 separately from the third RFIC 226 or as at least part of the third RFIC 226. In this case, the fourth RFIC 228 may convert a baseband signal generated by the second communication processor 214 to an RF signal (hereinafter, an intermediate frequency (IF) signal) of an intermediate frequency band (e.g., about 9 GHz to about 11 GHz) and transfer the IF signal to the third RFIC 226. The third RFIC 226 may convert the IF signal to a 5G Above 6RF signal. Upon reception, the 5G Above 6RF signal may be received from the second cellular network 294 (e.g., a 5G network) through an antenna (e.g., the antenna 248) and be converted to an IF signal by the third RFIC 226. The fourth RFIC 228 may convert an IF signal to a baseband signal so as to be processed by the second communication processor 214.

According to one embodiment, the first RFIC 222 and the second RFIC 224 may be implemented into at least part of a single package or a single chip. According to one embodiment, the first RFFE 232 and the second RFFE 234 may be implemented into at least part of a single package or a single chip. According to one embodiment, at least one of the first antenna module 242 or the second antenna module 244 may be omitted or may be combined with another antenna module to process RF signals of a corresponding plurality of bands.

According to one embodiment, the third RFIC 226 and the antenna 248 may be disposed at the same substrate to form a third antenna module 246. For example, the wireless communication module 192 or the processor 120 may be disposed at a first substrate (e.g., main PCB). In this case, the third RFIC 226 is disposed in a partial area (e.g., lower surface) of the first substrate and a separate second substrate (e.g., sub PCB), and the antenna 248 is disposed in another partial area (e.g., upper surface) thereof; thus, the third antenna module 246 may be formed. By disposing the third RFIC 226 and the antenna 248 in the same substrate, a length of a transmission line therebetween can be reduced. This may reduce, for example, a loss (e.g., attenuation) of a signal of a high frequency band (e.g., about 6 GHz to about 60 GHz) to be used in 5G network communication by a transmission line. Therefore, the electronic device 101 may improve a quality or speed of communication with the second cellular network 294 (e.g., 5G network).

According to one embodiment, the antenna 248 may be formed in an antenna array including a plurality of antenna elements that may be used for beamforming. In this case, the third RFIC 226 may include a plurality of phase shifters 238 corresponding to a plurality of antenna elements, for example, as part of the third RFFE 236. Upon transmission, each of the plurality of phase shifters 238 may convert a phase of a 5G Above6 RF signal to be transmitted to the outside (e.g., a base station of a 5G network) of the electronic device 101 through a corresponding antenna element. Upon reception, each of the plurality of phase shifters 238 may convert a phase of the 5G Above6 RF signal received from the outside to the same phase or substantially the same phase through a corresponding antenna element. This enables transmission or reception through beamforming between the electronic device 101 and the outside.

The second cellular network 294 (e.g., 5G network) may operate (e.g., stand-alone (SA)) independently of the first cellular network 292 (e.g., legacy network) or may be operated (e.g., non-stand alone (NSA)) in connection with the first cellular network 292. For example, the 5G network may have only an access network (e.g., 5G radio access network (RAN) or a next generation (NG) RAN and have no core network (e.g., next generation core (NGC)). In this case, after accessing to the access network of the 5G network, the electronic device 101 may access to an external network (e.g., Internet) under the control of a core network (e.g., an evolved packed core (EPC)) of the legacy network. Protocol information (e.g., LTE protocol information) for communication with a legacy network or protocol information (e.g., new radio (NR) protocol information) for communication with a 5G network may be stored in the memory 130 to be accessed by other components (e.g., the processor 120, the first communication processor 212, or the second communication processor 214).

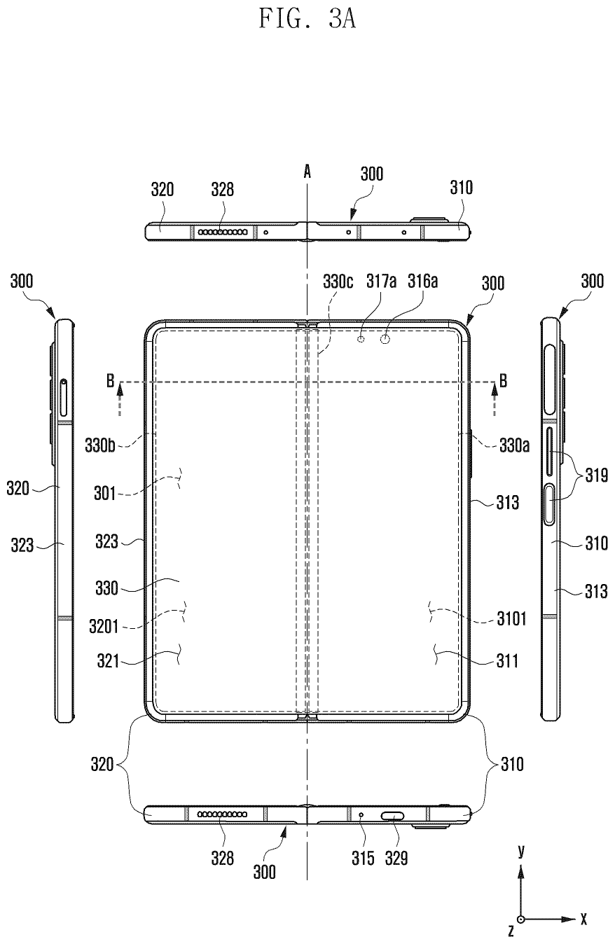

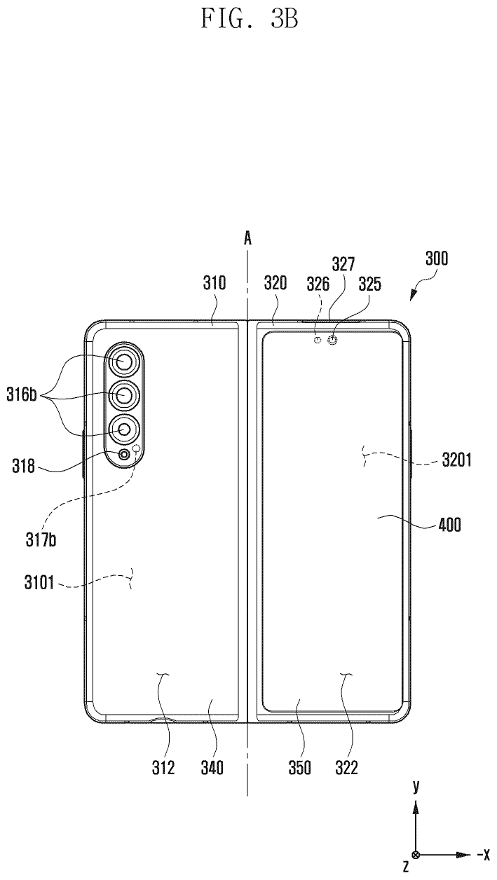

FIGS. 3A and 3B are views illustrating an unfolded state (unfolded stage) of the electronic device when viewed from front and rear surfaces thereof according to various embodiments of the disclosure.

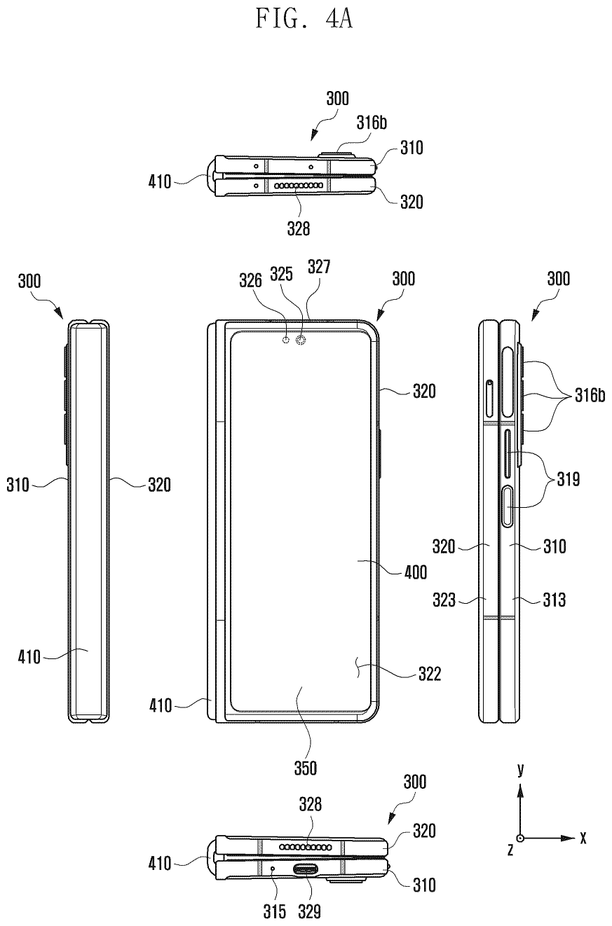

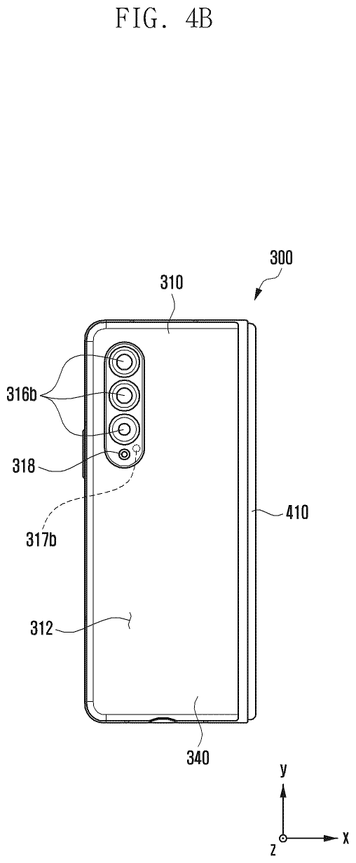

FIGS. 4A and 4B are views illustrating a folded state of the electronic device when viewed from the front and rear surfaces thereof according to various embodiments of the disclosure.

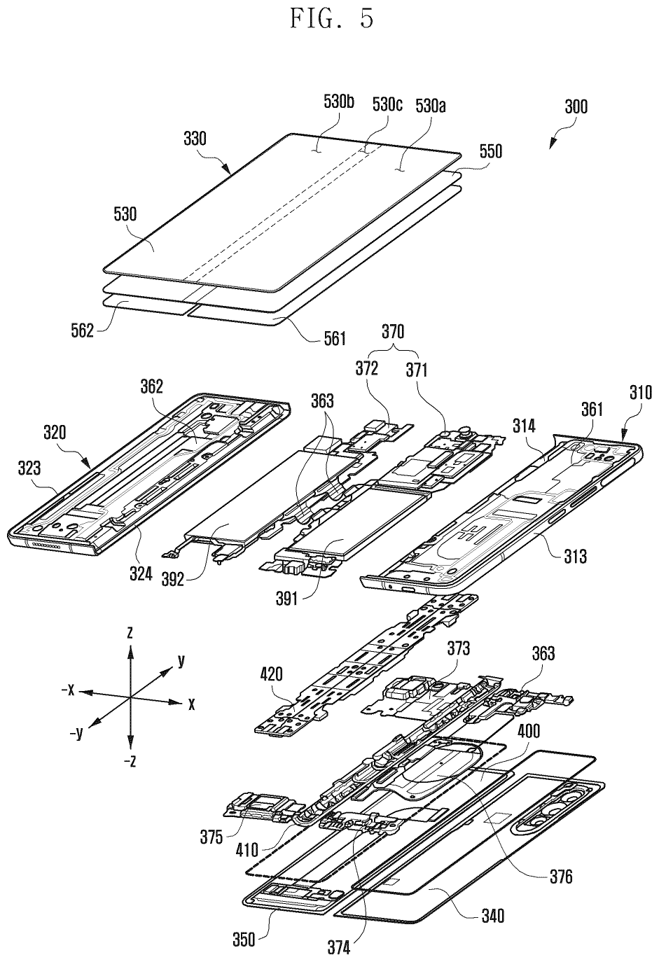

With reference to FIGS. 3A, 3B, 4A, and 4B, an electronic device 300 may include a pair of housings 310 and 320 (e.g., foldable housing structures) coupled to each other so as to be rotatable about a folding axis A by means of a hinge device (e.g., a hinge device 420 in FIG. 5) (e.g., a hinge module) and foldable with respect to each other, a first display 330 (e.g., a flexible display, a foldable display, or a main display) disposed by means of the pair of housings 310 and 320, and/or a second display 400 (e.g., a sub-display) disposed by means of the second housing 320. According to one embodiment, at least a part of the hinge device (e.g., the hinge device 420 in FIG. 5) may be disposed to be invisible from the outside by means of the first housing 310 and the second housing 320. In the unfolded state, at least a part of the hinge device may be disposed to be invisible from the outside by means of a hinge housing 410 configured to cover foldable parts. In the disclosure, a surface on which the first display 330 is disposed may be defined as a front surface of the electronic device 300, and a surface opposite to the front surface may be defined as a rear surface of the electronic device 300. In addition, a surface, which surrounds a space between the front surface and the rear surface, may be defined as a side surface of the electronic device 300.

According to various embodiments, the pair of housings 310 and 320 may include the first housing 310 and the second housing 320 disposed to be foldable with respect to each other by means of the hinge device (e.g., the hinge device 420 in FIG. 5). According to one embodiment, the pair of housings 310 and 320 is not limited by shapes and coupling illustrated in FIGS. 3A, 3B, 4A, and 4B and may be implemented by combination and/or coupling of other shapes or components. According to one embodiment, the first housing 310 and the second housing 320 may be disposed at two opposite sides based on the folding axis A and have an entirely symmetric shape with respect to the folding axis A. According to any embodiment, the first housing 310 and the second housing 320 may be folded asymmetrically with respect to the folding axis A. According to one embodiment, an angle or distance between the first housing 310 and the second housing 320 may vary depending on whether the electronic device 300 is in an unfolded state (unfolded stage), a folded state, or an intermediate state.

According to various embodiments, in the unfolded state of the electronic device 300, the first housing 310 may include a first surface 311 connected to the hinge device (e.g., the hinge device 420 in FIG. 5) and disposed to be directed toward the front surface of the electronic device 300, a second surface 312 directed in a direction opposite to the first surface 311, and/or a first lateral member 313 configured to surround at least a part of a first space between the first surface 311 and the second surface 312. According to one embodiment, in the unfolded state of the electronic device 300, the second housing 320 may include a third surface 321 connected to the hinge device (e.g., the hinge device 420 in FIG. 5) and disposed to be directed toward the front surface of the electronic device 300, a fourth surface 322 directed in a direction opposite to the third surface 321, and/or a second lateral member 323 configured to surround at least a part of a second space between the third surface 321 and the fourth surface 322. According to one embodiment, the first surface 311 is directed in substantially the same direction as the third surface 321 in the unfolded state, and the first surface 311 may at least partially face the third surface 321 in the folded state. According to one embodiment, the electronic device 300 may also include a recess 301 formed by structurally coupling the first housing 310 and the second housing 320 and configured to accommodate the first display 330. According to one embodiment, the recess 301 may have substantially the same size as the first display 330.

According to various embodiments, the hinge housing 410 (e.g., the hinge cover) may be disposed between the first housing 310 and the second housing 320 and disposed to cover a part of the hinge device (e.g., the hinge device 420 in FIG. 5) (e.g., at least one hinge module) disposed in the hinge housing 410. According to one embodiment, the hinge housing 410 may be covered by a part of the first housing 310 and a part of the second housing 320 or exposed to the outside in accordance with whether the electronic device 300 is in the unfolded state, the folded state, or the intermediate state. For example, in case that the electronic device 300 is in the unfolded state, at least a part of the hinge housing 410 may be covered by the first housing 310 and the second housing 320 and may not be substantially exposed. According to one embodiment, in case that the electronic device 300 is in the folded state, at least a part of the hinge housing 410 may be exposed to the outside between the first housing 310 and the second housing 320. According to one embodiment, in the intermediate state in which the first housing 310 and the second housing 320 define a predetermined angle therebetween (are folded with a certain angle), the hinge housing 410 may be disposed between the first housing 310 and the second housing 320 so that the hinge housing 410 is at least partially exposed to the outside of the electronic device 300. For example, an area of the hinge housing 410, which is exposed to the outside, may be smaller than an area of the hinge housing 410 exposed to the outside in the fully folded state. According to one embodiment, the hinge housing 410 may include a curved surface.

According to various embodiments, when the electronic device 300 is in the unfolded state (e.g., the state in FIGS. 3A and 3B), the first housing 310 and the second housing 320 may define an angle of about 180 degrees. A first area 330a, a second area 330b, and a folding area 330c of the first display 330 may be disposed on the same plane and directed in substantially the same direction (e.g., a z-axis direction). In another embodiment, in case that the electronic device 300 is in the unfolded state, the first housing 310 may be rotated by an angle of about 360 degrees relative to the second housing 320 and folded reversely so that the second surface 312 and the fourth surface 322 face each other (out-folding manner).

According to various embodiments, in case that the electronic device 300 is in the folded state (e.g., the state in FIGS. 4A and 4B), the first surface 311 of the first housing 310 and the third surface 321 of the second housing 320 may be disposed to face each other. In this case, the first area 330a and the second area 330b of the first display 330 may also be disposed to face each other while defining a narrow angle (e.g., within a range of 0 to about 10 degrees) therebetween by means of the folding area 330c. According to one embodiment, at least a part of the folding area 330c may be deformed in a curved shape having a predetermined curvature. According to one embodiment, in case that the electronic device 300 is in the intermediate state, the first housing 310 and the second housing 320 may be disposed at a predetermined angle (a certain angle) with respect to each other. In this case, the first area 330a and the second area 330b of the first display 330 may define an angle larger than an angle in the folded state and smaller than an angle in the unfolded state. A curvature of the folding area 330c may be smaller than a curvature in the folded state and larger than a curvature in the unfolded state. In any embodiment, the first housing 310 and the second housing 320 may define an angle by means of the hinge device (e.g., the hinge device 420 in FIG. 5) so that the first housing 310 and the second housing 320 may be stopped at a designated folding angle between the folded state and the unfolded state (free stop function). In any embodiment, the first housing 310 and the second housing 320 may operate consistently while being pressed in an unfolding direction or a folding direction based on a designated inflection angle by means of the hinge device (e.g., the hinge device 420 in FIG. 5).

According to various embodiments, the electronic device 300 may include at least one of at least one of displays 330 and 400 disposed in the first housing 310 and/or the second housing 320, an input device 315, sound output devices 327 and 328, sensor modules 317a, 317b, and 326, camera modules 316a, 316b, and 325, key input devices 319, an indicator (not illustrated), and a connector port 329. In any embodiment, the electronic device 300 may exclude at least one of the constituent elements or further include at least one of other constituent elements.

According to various embodiments, at least one of the displays 330 and 400 may include the first display 330 (e.g., the flexible display) disposed to be supported by the third surface 321 of the second housing 320 from the first surface 311 of the first housing 310 by means of the hinge device (e.g., the hinge device 420 in FIG. 5), and the second display 400 disposed in an internal space of the second housing 320 so as to be at least partially visible from the outside through the fourth surface 322. In any embodiment, the second display 400 may also be disposed in an internal space of the first housing 310 so as to be visible from the outside through the second surface 312. According to one embodiment, the first display 330 may be mainly used when the electronic device 300 is in the unfolded state, and the second display 400 may be mainly used when the electronic device 300 is in the folded state. According to one embodiment, in the intermediate state, the electronic device 300 may control the first display 330 and/or the second display 400 on the basis of a folding angle between the first housing 310 and the second housing 320 so that the first display 330 and/or the second display 400 may be used.

According to various embodiments, the first display 330 may be disposed in an accommodation space defined between the pair of housings 310 and 320. For example, the first display 330 may be disposed in the recess 301 defined by the pair of housings 310 and 320 and disposed to occupy the substantially most part of the front surface of the electronic device 300 in the unfolded state. According to one embodiment, the first display 330 may include a flexible display having at least a partial area that may be deformed to a flat or curved surface. According to one embodiment, the first display 330 may include the first area 330a configured to face the first housing 310, the second area 330b configured to face the second housing 320, and the folding area 330c configured to connect the first area 330a and the second area 330b and face the hinge device (e.g., the hinge device 420 in FIG. 5). According to one embodiment, the division of the area of the first display 330 is just a physical division made by the pair of housings 310 and 320 and the hinge device (e.g., the hinge device 420 in FIG. 5). The first display 330 may substantially display a single seamless entire screen through the pair of housings 310 and 320 and the hinge device (e.g., the hinge device 420 in FIG. 5). According to one embodiment, the first area 330a and the second area 330b may have an entirely symmetric shape or a partially asymmetric shape based on the folding area 330c.

According to various embodiments, the electronic device 300 may include a first rear surface cover 340 disposed on the second surface 312 of the first housing 310, and a second rear surface cover 350 disposed on the fourth surface 322 of the second housing 320. In any embodiment, at least a part of the first rear surface cover 340 may be integrated with the first lateral member 313. In any embodiment, at least a part of the second rear surface cover 350 may be integrated with the second lateral member 323. According to one embodiment, at least one of the first and second rear surface covers 340 and 350 may each be provided in the form of a substantially transparent plate (e.g., a glass or polymer plate including various coating layers) or an opaque plate. According to one embodiment, for example, the first rear surface cover 340 may be provided in the form of an opaque plate made of coated or tinted glass, ceramic, polymer, metal (e.g., aluminum, stainless steel (STS), or magnesium), or a combination of at least two of the above-mentioned materials. According to one embodiment, for example, the second rear surface cover 350 may be provided in the form of a substantially transparent plate made of glass, polymer, or the like. Therefore, the second display 400 may be disposed in the internal space of the second housing 320 so as to be visible from the outside through the second rear surface cover 350.

According to various embodiments, the input device 315 may include a microphone. In any embodiment, the input device 315 may include a plurality of microphones disposed to detect a direction of sound. According to one embodiment, the sound output devices 327 and 328 may include speakers. According to one embodiment, the sound output devices 327 and 328 may include a telephone receiver disposed by means of the fourth surface 322 of the second housing 320, and an external speaker 328 disposed by means of at least a part of the second lateral member 323 of the second housing 320. In any embodiment, the input device 315, the sound output devices 327 and 328, and the connector port 329 may be disposed in spaces of the first housing 310 and/or the second housing 320 and exposed to an external environment through at least one hole formed in the first housing 310 and/or the second housing 320. In any embodiment, the holes formed in the first housing 310 and/or the second housing 320 may be used in common for the input device 315 and the sound output devices 327 and 328. In any embodiment, the sound output devices 327 and 328 may include speakers (e.g., piezoelectric speakers) that operate without holes formed in the first housing 310 and/or the second housing 320.

According to various embodiments, the camera modules 316a, 316b, and 325 may include a first camera module 316a disposed on the first surface 311 of the first housing 310, a second camera module 316b disposed on the second surface 312 of the first housing 310, and/or a third camera module 325 disposed on the fourth surface 322 of the second housing 320. According to one embodiment, the electronic device 300 may include a flash 318 disposed in the vicinity of the second camera module 316b. According to one embodiment, for example, the flash 318 may include a light-emitting diode or a xenon lamp. According to one embodiment, the camera modules 316a, 316b, and 325 may each include one lens or a plurality of lenses, an image sensor, and/or an image signal processor. In any embodiment, at least one of the camera modules 316a, 316b, and 325 may include two or more lenses (e.g., a wide-angle lens and a telephoto lens) and image sensors and be disposed together on any one surface of the first housing 310 and/or the second housing 320.

According to various embodiments, the sensor modules 317a, 317b, and 326 may generate electrical signals or data values corresponding to an internal operating state of the electronic device 300 or the external environment state. According to one embodiment, the sensor modules 317a, 317b, and 326 may include a first sensor module 317a disposed on the first surface 311 of the first housing 310, a second sensor module 317b disposed on the second surface 312 of the first housing 310, and/or a third sensor module 326 disposed on the fourth surface 322 of the second housing 320. In any embodiment, the sensor modules 317a, 317b, and 326 may include at least one of a gesture sensor, a grip sensor, a color sensor, an infrared (IR) sensor, an illuminance sensor, an ultrasonic sensor, an iris recognition sensor, and a distance detection sensor (e.g., a time-of-flight (TOF) sensor or a light detection and ranging (LiDAR) sensor).

According to various embodiments, the electronic device 300 may further include at least one of the non-illustrated sensor modules, e.g., an atmospheric pressure sensor, a magnetic sensor, a biosensor, a temperature sensor, a humidity sensor, and a fingerprint recognition sensor. In any embodiment, the fingerprint recognition sensor may be disposed by means of at least one of the first lateral member 313 of the first housing 310 and/or the second lateral member 323 of the second housing 320.

According to various embodiments, the key input devices 319 may be disposed to be exposed to the outside through the first lateral member 313 of the first housing 310. In any embodiment, the key input devices 319 may be disposed to be exposed to the outside through the second lateral member 323 of the second housing 320. In any embodiment, the electronic device 300 may exclude some or all of the key input devices 319, and the excluded key input device 319 may be implemented as other types such as a soft key on at least one of the displays 330 and 400. In another embodiment, the key input device 319 may be implemented by using a pressure sensor included in at least one of the displays 330 and 400.

According to various embodiments, the connector port 329 may include a connector (e.g., a USB connector or an interface connector port module (IF module)) configured to transmit or receive power and/or data to or from an external electronic device. In any embodiment, the connector port 329 may serve to transmit or receive audio signals to or from the external electronic device or further include a separate connector port (e.g., an earphone jack hole) for transmitting or receiving audio signals to or from the external electronic device.

According to various embodiments, at least one of the camera modules 316a and 325 among the camera modules 316a, 316b, and 325, at least one of the sensor modules 317a and 326 among the sensor modules 317a, 317b, and 326, and/or the indicator may be disposed to be exposed through at least one of the displays 330 and 400. For example, at least one of the camera modules 316a and 325, at least one of the sensor modules 317a and 326, and/or the indicator may be provided in the internal space of at least one of the housings 310 and 320, disposed below an activation area (display area) of at least one of the displays 330 and 400, and disposed to adjoin the external environment through a transparent area or an opening bored to a cover member (e.g., a window layer (not illustrated) of the first display 330 and/or the second rear surface cover 350). According to one embodiment, an area, in which at least one of the displays 330 and 400 faces at least one of the camera modules 316a and 325, may be a part of the area for displaying content and defined as a transmissive area having a predetermined transmittance rate. According to one embodiment, the transmissive area may be formed to have a transmittance rate within a range of about 5% to about 20%. The transmissive area may include an area that overlaps an effective area (e.g., a view angle area) of at least one of the camera modules 316a and 325 through which light, which enters an image sensor to create an image, passes. For example, the transmissive area of the display 330 or 400 may include an area having a lower pixel density than the periphery thereof. For example, the transmissive area may be substituted for the opening. For example, at least one of the camera modules 316a and 325 may include an under-display camera (UDC) or an under-panel camera (UPC). In another embodiment, some of the camera modules or some of the sensor modules 317a and 326 may be disposed to perform the functions thereof without being visually exposed through the display. For example, an area, which faces the camera modules 316a and 325 and/or the sensor modules 317a and 326 disposed below the displays 330 and 400 (e.g., the display panels), is an under-display camera (UDC) structure that does not require the bored opening.

FIG. 5 is an exploded perspective view of the electronic device 300 according to an embodiment of the disclosure.

With reference to FIG. 5, the electronic device 300 may include the first display 330 (e.g., the flexible display), the second display 400, the hinge device 420, a pair of support members 361 and 362, at least one substrate 370 (e.g., a printed circuit board (PCB)), the first housing 310, the second housing 320, the first rear surface cover 340, and/or the second rear surface cover 350.

According to various embodiments, the first display 330 may include a display panel 530 (e.g., a flexible display panel), a support plate 550 disposed below the display panel 530, and a pair of reinforcement plates 561 and 562 disposed below the support plate 550. According to one embodiment, the display panel 530 may include a first panel area 530a configured to correspond to the first area (e.g., the first area 330a in FIG. 3A) of the first display 330, a second panel area 530b extending from the first panel area 530a and configured to correspond to the second area (e.g., the second area 330b in FIG. 3A) of the first display 330, and a third panel area 530c configured to connect the first panel area 530a and the second panel area 530b and correspond to the folding area (e.g., the folding area 330c in FIG. 3A) of the first display 330. According to one embodiment, the support plate 550 may be disposed between the display panel 530 and the pair of support members 361 and 362 and formed to have a material and shape for providing flat support structures for the first panel area 530a and the second panel area 530b and providing a bendable structure for assisting in providing flexibility of the third panel area 530c. According to one embodiment, the support plate 550 may be made of a conductive material (e.g., metal) or a non-conductive material (e.g., polymer or fiber-reinforced plastic (FRP)). According to one embodiment, between the support plate 550 and the pair of support members 361 and 362, the pair of reinforcement plates 561 and 562 may include a first reinforcement plate 561 disposed to at least partially correspond to the first panel area 530a and the third panel area 530c, and a second reinforcement plate 562 disposed to at least partially correspond to the second panel area 530b and the third panel area 530c. According to one embodiment, the pair of reinforcement plates 561 and 562 may be made of a metallic material (e.g., SUS), which may assist in providing a ground connection structure and rigidity reinforcement for the first display 330.

According to various embodiments, the second display 400 may be disposed in a space between the second housing 320 and the second rear surface cover 350. According to one embodiment, the second display 400 may be disposed in the space between the second housing 320 and the second rear surface cover 350 and visible from the outside through a substantially overall area of the second rear surface cover 350.

According to various embodiments, at least a part of the first support member 361 may be coupled to the second support member 362 and configured to be foldable by means of the hinge device 420. According to one embodiment, the electronic device 300 may include at least one wiring member (e.g., a flexible printed circuit board (FPCB)) disposed to a part of the second support member 362 from at least a part of the first support member 361 while traversing the hinge device 420. According to one embodiment, the first support member 361 may extend from the first lateral member 313 or be disposed to be structurally coupled to the first lateral member 313. According to one embodiment, the electronic device 300 may include a first space (e.g., a first space 3101 in FIG. 3A) provided by the first support member 361 and the first rear surface cover 340. According to one embodiment, the first housing 310 (e.g., a first housing structure) may be configured by coupling the first lateral member 313, the first support member 361, and the first rear surface cover 340. According to one embodiment, the second support member 362 may extend from the second lateral member 323 or be disposed to be structurally coupled to the second lateral member 323. According to one embodiment, the electronic device 300 may include a second space (e.g., a second space 3201 in FIG. 3A) provided by the second support member 362 and the second rear surface cover 350. According to one embodiment, the second housing 320 (e.g., a second housing structure) may be configured by coupling the second lateral member 323, the second support member 362, and the second rear surface cover 350. According to one embodiment, at least one wiring member and/or at least a part of the hinge device 420 may be disposed to be supported by at least a part of the pair of support members 361 and 362. According to one embodiment, at least one wiring member may be disposed in a direction (e.g., an x-axis direction) that traverses the first support member 361 and the second support member 362. According to one embodiment, at least one wiring member may be disposed in the direction (e.g., the x-axis direction) substantially perpendicular to the folding axis (e.g., the y-axis or the folding axis A in FIG. 3A).

According to various embodiments, at least one substrate 370 may include a first substrate 371 disposed in the first space 3101, and a second substrate 372 disposed in the second space 3201. According to one embodiment, the first substrate 371 and the second substrate 372 may include a plurality of electronic components disposed to implement various functions of the electronic device 300. According to one embodiment, the first substrate 371 and the second substrate 372 may be electrically connected by at least one wiring member.

According to various embodiments, the electronic device 300 may include one or more batteries 391 and 392. According to one embodiment, one or more batteries 391 and 392 may include a first battery 391 disposed in the first space 3101 of the first housing 310 and electrically connected to the first substrate 371, and a second battery disposed in the second space 3201 of the second housing 320 and electrically connected to the second substrate 372. According to one embodiment, the first support member 361 and the second support member 362 may each further include at least one swelling hole for the first battery 391 and a second battery 392.

According to various embodiments, the first housing 310 may include a first rotation support surface 314, and the second housing 320 may include a second rotation support surface 324 corresponding to the first rotation support surface 314. According to one embodiment, the first rotation support surface 314 and the second rotation support surface 324 may each include a curved surface corresponding to (naturally connected to) an outer surface of a curved shape of the hinge housing 410. According to one embodiment, in case that the electronic device 300 is in the unfolded state, the first rotation support surface 314 and the second rotation support surface 324 may cover the hinge housing 410, such that the hinge housing 410 may not be exposed to or may be only partially exposed to the rear surface of the electronic device 300. According to one embodiment, in case that the electronic device 300 is in the folded state, the first rotation support surface 314 and the second rotation support surface 324 may rotate along the outer surface of the curved shape of the hinge housing 410, such that the hinge housing 410 may be at least partially exposed to the rear surface of the electronic device 300.

According to various embodiments, the electronic device 300 may include at least one antenna 376 disposed in the first space 3301. According to one embodiment, at least one antenna 376 may be disposed in the first space 3301 and disposed between the first battery 391 and the first rear surface cover 340. According to one embodiment, for example, at least one antenna 376 may include a near-field communication (NFC) antenna, a wireless charging antenna, and/or a magnetic secure transmission (MST) antenna. According to one embodiment, for example, at least one antenna 376 may perform near-field communication with an external device or transmit or receive electric power required for charging in a wireless manner. In any embodiment, an antenna structure may be formed by at least a part of the first lateral member 313 or at least a part of the second lateral member 323, and/or a part of the first support member 361 and a part of the second support member 362, or a combination thereof.

According to various embodiments, the electronic device 300 may further include one or more electronic component assemblies 374 and 375 and/or additional support members 363 and 373 disposed in the first space 3101 and/or the second space 3201. For example, at least one electronic component assembly may include an interface connector port assembly 374 or a speaker assembly 375.

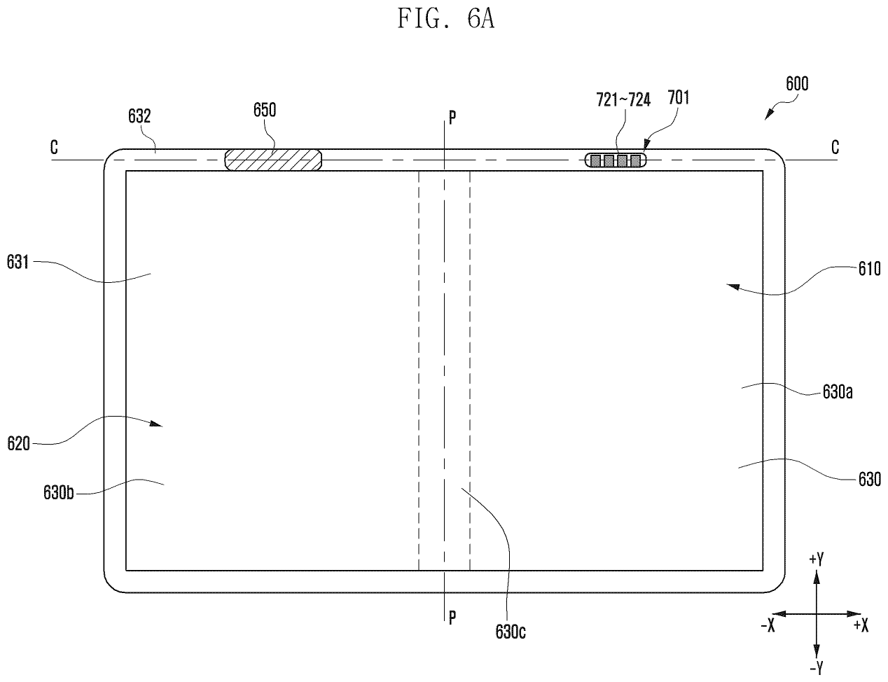

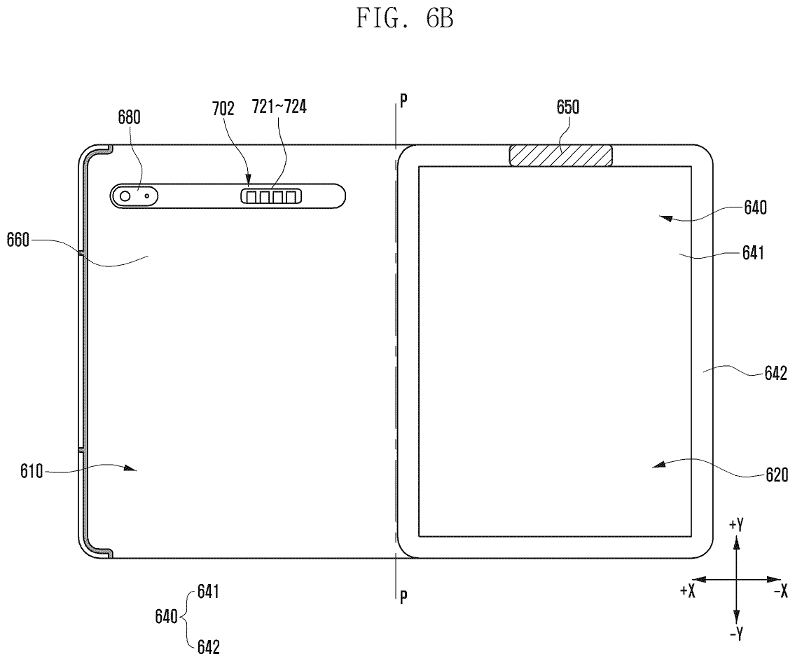

FIG. 6A is a view illustrating the front surface of the electronic device illustrated in FIGS. 3A, 3B, 4A, 4B, and 5 and a front surface of an electronic device when in the unfolded state according to an embodiment of the disclosure.

FIG. 6B is a view illustrating the rear surface of the electronic device illustrated in FIGS. 3A, 3B, 4A, 4B, and 5 and a rear surface of the electronic device when in the unfolded state according to an embodiment of the disclosure.

An electronic device 600 to be described below may include at least one of the constituent elements of the electronic device (e.g., the electronic device 101 in FIG. 1 or the electronic device 300 in FIG. 3A) described above.

Referring to FIGS. 6A and 6B, the electronic device 600 according to various embodiments disclosed in the disclosure may include a first housing 610 (e.g., the first housing 310 in FIG. 3A) and a second housing 620 (e.g., the second housing 320 in FIG. 3A) connected to a hinge device 810 (e.g., the hinge device 420 (e.g., the hinge module) in FIG. 5) and configured to be rotatable about a folding axis P-P, a first display 630 (e.g., the first display 330 in FIG. 3A) disposed toward a front surface of the electronic device 600, a second display 640 (e.g., the second display 400 in FIG. 3B) disposed on a rear surface opposite to the front surface, and a cover member 660 configured to define an external appearance of the electronic device 600 and disposed toward the rear surface of the electronic device 600. The first display 630 may be a flexible display that may be at least partially deformed. For example, the first display 630 may include a first area 630a disposed on the first housing 610, a second area 630b disposed on the second housing 620, and a deformation area 630c positioned between the first area 630a and the second area 630b and configured to be deformed when the electronic device 600 is folded about the folding axis P-P. The second display 640 may be disposed on one of the first housing 610 and the second housing 620 and directed toward the rear surface of the electronic device 600. The cover member 660 may be disposed on the remaining housing on which the second display 640 is not disposed. For example, with reference to FIG. 6B, the second display 640 may be disposed on the second housing 620 and directed toward the rear surface of the electronic device 600. In addition, the cover member 660 may be disposed on the first housing 610 and directed toward the rear surface of the electronic device 600. In the embodiment, a camera module 680 (e.g., the camera module 316b in FIG. 3B) may be disposed on one of the first housing 610 and the second housing 620 and directed toward the rear surface of the electronic device 600. For example, with reference to FIG. 6B, the camera module 680 may be disposed on the first housing 610 and directed toward the rear surface of the electronic device 600.

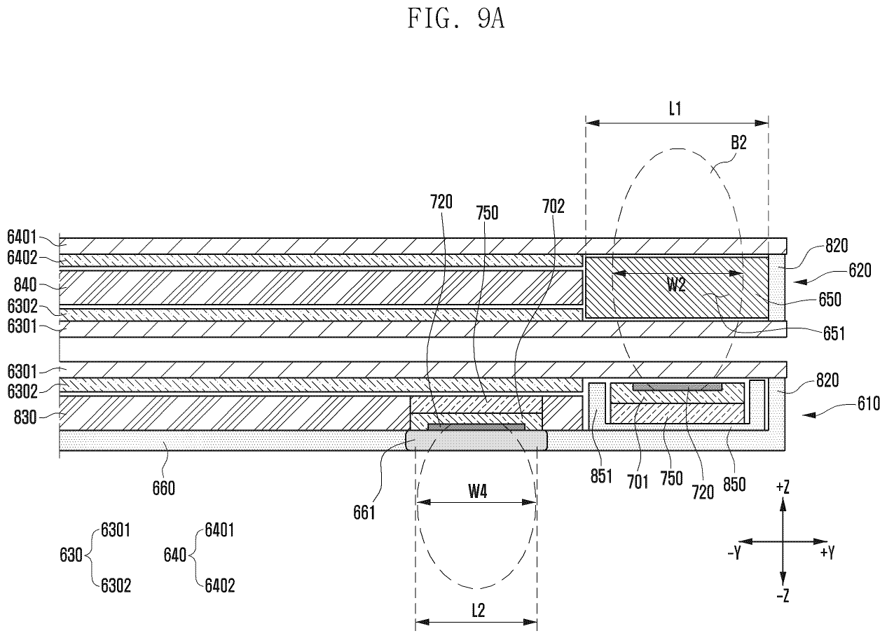

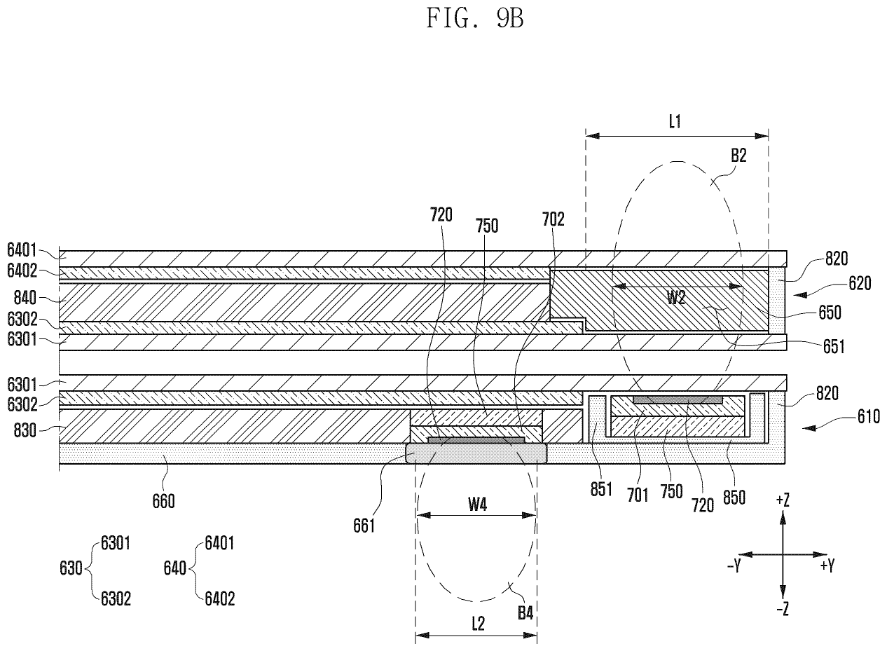

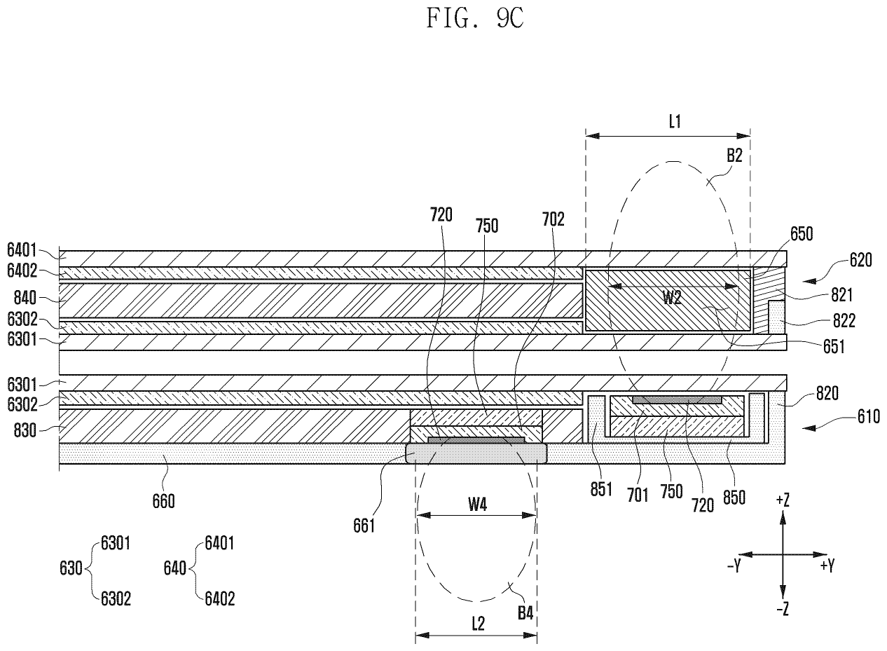

According to various embodiments, the first display 630 may include a first window layer 6301, a polarizing film (not illustrated) and a first display panel 6302 sequentially disposed on a rear surface of the first window layer 6301 (e.g., a-z direction based on FIG. 9A), a polymer layer (not illustrated) configured to provide a dark background to ensure visibility of the first display panel 6302, and a support plate (not illustrated) configured to support the first display panel 6302. Likewise, the second display 640 may include a second window layer 6401, a polarizing film (not illustrated) and a second display panel 6402 sequentially disposed on a rear surface of the second window layer 6401 (e.g., a +z direction based on FIG. 9A), a polymer layer (not illustrated) configured to provide a dark background to ensure visibility of the second display panel 6402, and a support plate (not illustrated) configured to support the second display panel 6402. In any embodiment, a digitizer (not illustrated) may be disposed below the support plate of the first display 630 and the support plate of the second display 640.

According to various embodiments, an antenna module 700 may be disposed in the electronic device 600. The antenna module 700 may be disposed on at least one of the first housing 610 and the second housing 620. The antenna module 700 may receive radio waves provided by a repeater of a carrier or transmit radio waves. In the embodiment, the antenna module 700 may be an mmWave antenna module. The antenna module 700 may transmit or receive a signal in a designated high-frequency band (e.g., an mmWave band). In any embodiment, the antenna module 700 may include a near-field communication (NFC) antenna, a wireless charging antenna, and/or a magnetic secure transmission (MST) antenna. For example, the antenna module 700 may perform near-field communication with an external device or transmit or receive electric power required for charging in a wireless manner.

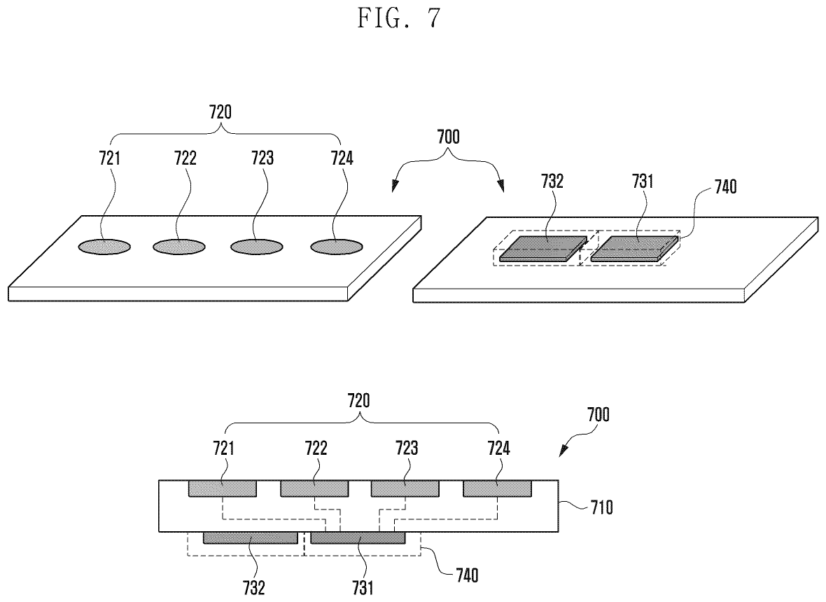

According to various embodiments, the antenna module 700 may include an array antenna (e.g., an antenna patch) (e.g., an array antenna 720 in FIG. 7). The array antenna may transmit or receive a signal in a designated high-frequency band (e.g., an mmWave band). For example, the antenna module 700 may transmit or receive ultra-high frequencies in 3.5 GHz to 28 GHz and 28 GHz to 100 GHz bands used for 5G communication through the array antenna 720. The antenna module 700 may concentratedly transmit or receive radio waves in a particular direction through the array antenna 720.

According to various embodiments, as illustrated in FIGS. 6A and 6B, the antenna module 700 may include a plurality of antennas. In the embodiment, the antenna module 700 may include a first antenna module 701 and a second antenna module 702. The first antenna module 701 may be disposed on at least one of the first housing 610 and the second housing 620. In the embodiment, the first antenna module 701 may be disposed on at least one of the first housing 610 and the second housing 620 so that the array antenna 720 faces the first display 630 disposed on the front surface of the electronic device 600. In the embodiment, with reference to FIG. 6A, the first antenna module 701 may be disposed on the first housing 610 so that the array antenna 720 faces the first display 630. The first antenna module 701 may be disposed on the first housing 610 so as to face an opaque area (e.g., a black matrix (BM) area) 632 configured to surround a display area 631 of the first display 630. In this case, the first antenna module 701 may radiate communication signals in a direction identical to a direction in which the first display 630 is directed. In the embodiment, with reference to FIG. 6B, the second antenna module 702 may be disposed on at least one of the first housing 610 and the second housing 620. The second antenna module 702 may be disposed on at least one of the first housing 610 and the second housing 620 so that the array antenna 720 is directed toward the cover member 660 disposed on the rear surface of the electronic device 600. In the embodiment, with reference to FIG. 6B, the second antenna module 702 may be disposed on the first housing 610 so that the array antenna 720 is directed toward the cover member 660. In this case, one area of the cover member 660, which faces the second antenna module 702, may be made of a nonmetallic material so that the communication signal of the second antenna module 702 may pass through the cover member 660.

Hereinafter, for convenience of description, the description will be described on the premise that the first antenna module 701 and the second antenna module 702 are disposed on the first housing 610. However, the following description does not limit positions of the first antenna module 701 and the second antenna module 702. In the embodiment, the first antenna module 701 and the second antenna module 702 may be disposed on the second housing 620. In any embodiment, the first antenna module 701 may be disposed on the first housing 610 and the second antenna module 702 may be disposed on the second housing 620 or vice versa.

FIG. 7 is a view illustrating a structure of the antenna module according to an embodiment of the disclosure.

According to various embodiments, as illustrated in FIG. 7, the antenna module 700 may include a substrate 710, the array antenna 720, a radio frequency integrated circuit (RFIC) 731, or a power manage integrated circuit (PMIC) 732. Selectively, the antenna module 700 may further include a shield member 740. In other embodiments, at least one of the above-mentioned components may be excluded, or at least two components among the component may be integrated.

In the embodiment, the substrate 710 may include a plurality of conductive layers, and a plurality of non-conductive layers stacked alternately with the conductive layers. The substrate 710 may provide electrical connection between various electronic components disposed on the substrate 710 and/or disposed outside by using lines and conductive vias formed on the conductive layers.

In one embodiment, the array antenna 720 (e.g., 248 in FIG. 2) may include a plurality of antenna elements 721, 722, 723, and 724 disposed to form directional beams. The plurality of antenna elements 721, 722, 723, and 724 may include a plurality of conductive patches and/or a plurality of conductive patterns. As illustrated in FIG. 7, the antenna elements 721, 722, 723, and 724 may be formed on a first surface of the substrate 710. According to another embodiment, the array antenna 720 may be formed in the substrate 710. According to the embodiments, the array antenna 720 may include a plurality of array antennas (e.g., a dipole array antenna and/or a patch array antenna) with the same shape or type or different shapes or types.

The RFIC 731 (e.g., 226 in FIG. 2) may be disposed in another area of the substrate 710 (e.g., a second surface opposite to the first surface) spaced apart from the array antenna 720. The RFIC 731 is configured to process a signal (an RF signal or a communication signal) in a selected frequency band (e.g., a frequency band in 3 GHZ to 100 GHz ranges) transmitted/received through the array antenna 720. For example, the RFIC 731 may be configured to form directional beams through the array antenna 720. According to the embodiment, when the RFIC 731 transmits the signal, the RFIC 731 may convert a baseband signal, which is acquired from a communication processor (not illustrated), into an RF signal in a designated band. When the RFIC 731 receives the signal, the RFIC 731 may convert an RF signal, which is received through the array antenna 720, into a baseband signal and transmit the baseband signal to the communication processor.

According to another embodiment, when the RFIC 731 transmits the signal, the RFIC 731 may up-convert an IF signal (e.g., about 9 GHz to about 11 GHz), which is acquired from an intermediate frequency integrated circuit (IFIC) (e.g., 228 in FIG. 2), into an RF signal in a selected band. When the RFIC 731 receives the signal, the RFIC 731 may down-convert an RF signal, which is acquired through the array antenna 720, into an IF signal and transmit the IF signal to the IFIC.

The PMIC 732 may be disposed in another partial area (e.g., the second surface) of the substrate 710 spaced apart from the array antenna 720. The PMIC 732 may be supplied with a voltage from a printed circuit board (e.g., a first printed circuit board 830 (e.g., the substrate 370 in FIG. 5) or a second printed circuit board 840 (e.g., the substrate 370 in FIG. 5)) and provide power required for various components (e.g., an RFIC 452) on the antenna module 700.

The shield member 740 may be disposed on a part (e.g., the second surface) of the substrate 710 to electromagnetically shield at least one of the RFIC 731 or the PMIC 732. According to one embodiment, the shield member 740 may include a shield can.

Although not illustrated, in various embodiments, the antenna module 700 may be electrically connected to another printed circuit board (e.g., the first printed circuit board 830 or the second printed circuit board 840) through a module interface. The module interface may include a connection member, e.g., a coaxial cable connector, a board-to-board connector, an interposer, or a flexible printed circuit board (FPCB). The RFIC 731 and/or the PMIC 732 of the antenna module may be electrically connected to the printed circuit board through the connection member.

According to various embodiments, the performance of the antenna module 700 for transmitting or receiving a signal in a designated frequency band (e.g., a high-frequency band) may be degraded in case that a mechanism (e.g., a printed circuit board or an electronic component) made of a metallic material is present at a position adjacent to the antenna module 700. For example, in case that the electronic device is folded about the folding axis P-P, the first antenna module 701 disposed on the first housing 610 may face a mechanism or electronic component disposed on the second housing 620 and made of a metallic material. In this case, the performance in transmitting high-frequency band signals radiated from the first antenna module 701 or the performance in receiving signals radiated from an external electronic device may be degraded. According to various embodiments disclosed in the disclosure, the second housing 620 may include a radiation part 650. The radiation part 650 may face the first antenna module 701 in the state in which the electronic device 600 (e.g., the electronic device 101 in FIG. 1 or the electronic device 300 in FIG. 3A) is folded about the folding axis P-P. The first antenna module 701 may transmit or receive a communication signal through the radiation part 650. Hereinafter, the radiation part 650 will be described in detail.

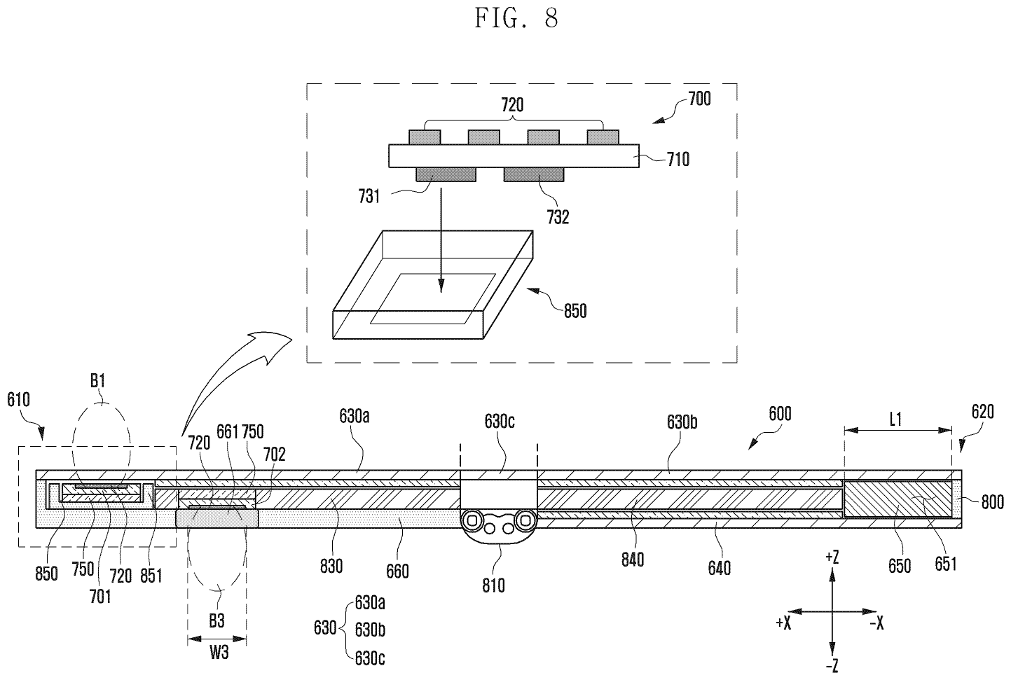

FIG. 8 is a cross-sectional view of the electronic device taken along line C-C in FIG. 6A according to an embodiment of the disclosure.

FIGS. 9A, 9B, and 9C are views illustrating states in which the first antenna module and the radiation part face each other in the state in which the electronic device illustrated in FIG. 8 is folded according to various embodiments of the disclosure.

According to various embodiments, as illustrated in FIGS. 8, 9A, 9B, and 9C, the second housing 620 (e.g., the second housing 320 in FIG. 3A) may include the radiation part 650 through which a communication signal related to the first antenna module 701 disposed on the first housing 610 (e.g., the first housing 310 in FIG. 3A) passes in the state in which the electronic device 600 is folded (or the folded state). The radiation part 650 may be formed on the second housing 620 so as to correspond to the first antenna module 701 disposed on the first housing 610 in the state in which the electronic device 600 is folded. The radiation part 650 may include a non-conductive area so that radio waves radiated from the first antenna module 701 pass through the non-conductive area. For example, a mechanism or electronic component made of a metallic material may not be disposed on the radiation part 650. In the embodiment, the radiation part 650 may include an internal space (e.g., an air gap) 651 that faces the first antenna module 701 in the state in which the electronic device 600 is folded. The internal space 651 of the radiation part 650 may be a non-conductive area, and a mechanism or electronic component made of a metallic material may not be disposed in the internal space 651. Therefore, in the state in which the electronic device 600 is folded, the first antenna module 701 may transmit or receive a signal in a designated frequency band through the radiation part 650. In another embodiment, an injection-molded product made of a nonmetallic material may be disposed in the radiation part 650. The injection-molded product, which fills the radiation part 650, may be a material that does not degrade the performance in transmitting the communication signal generated by the first antenna module 701 or the performance in receiving the communication signal generated by the external electronic device 600. Therefore, in the state in which the electronic device 600 is folded, the first antenna module 701 may transmit or receive a signal in a designated frequency band through the radiation part 650.

In the embodiment, the first antenna module 701 may be disposed on the first housing 610 so as to face the opaque area (e.g., the BM area) 632 configured to surround the display area 631 of the first display 630 (e.g., the first display 330 in FIG. 3A). In the state in which the electronic device 600 is folded, the radiation part 650 may be formed at a position on the second housing 620 corresponding to the opaque area 632 of the first display 630 so that the radiation part 650 may face the first antenna module 701. Therefore, in the state in which the electronic device 600 is folded, the first antenna module 701 may transmit or receive a communication signal in a designated frequency band through the radiation part 650.

According to various embodiments, as illustrated in FIG. 8, the antenna module 700 may be disposed in a seating part 850. In the embodiment, the first antenna module 701 may be seated in the seating part 850 disposed in the first housing 610. The seating part 850 may include a partition wall 851 configured to surround the first antenna module 701, and an opening 852 configured to face the array antenna 720 of the first antenna module 701. Heat generated by an operation of the first antenna module 701 may be transferred to the seating part 850 made of a metallic material and/or a nonmetallic material. For example, a heat transfer material (e.g., a thermal interface material (TIM)) 750 may be disposed between the first antenna module 701 and the seating part 850. Heat generated from the first antenna module 701 may be transferred to the seating part 850 through the heat transfer material 750 and diffused to the surrounding. Therefore, because the amount of heat generation is reduced, the first antenna module 701 may maintain the communication performance at a predetermined level or higher. Although not illustrated in the drawings, the second antenna module 702 may be seated in the seating part 850 disposed in the first housing 610. Heat generated from the second antenna module 702 may be transferred to the seating part 850 and diffused to the surrounding. Therefore, because the amount of heat generation is reduced, the second antenna module 702 may maintain the communication performance at a predetermined level or higher.

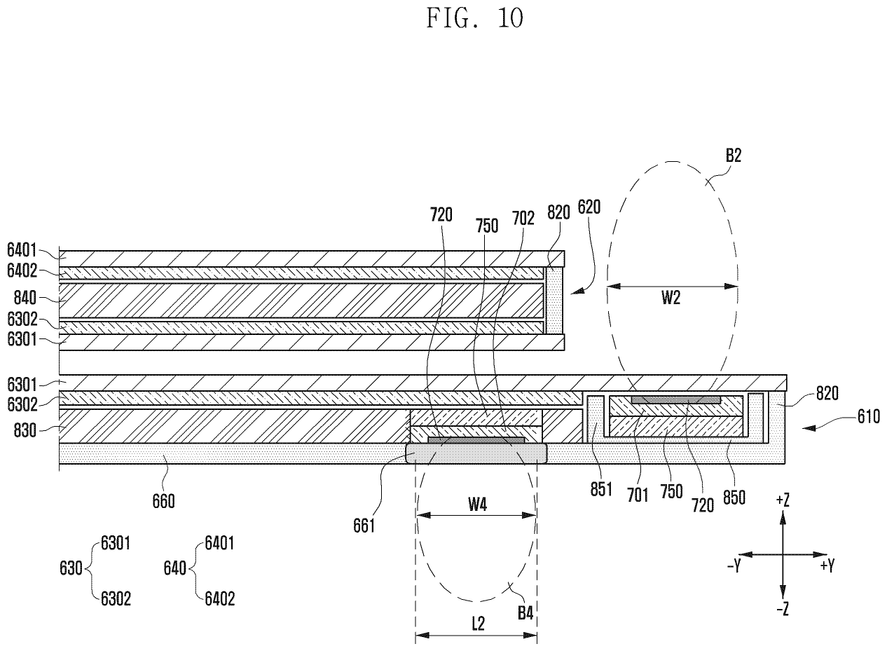

According to various embodiments, different directional beam patterns may be formed by the antenna module 700 in the state in which the electronic device 600 is folded or unfolded. In the embodiment, the processor (e.g., the processor 120 in FIG. 1) may control a beam pattern of the antenna module 700 depending on a relative position of the first housing 610 and a relative position of the second housing 620. In the embodiment, with reference to FIG. 8, in the state in which the electronic device 600 is unfolded, the processor may control the first antenna module 701 so that the first antenna module 701 forms a first beam pattern B1 by means of the array antenna 720. In addition, in the state in which the electronic device 600 is unfolded, the processor may control the second antenna module 702 so that the second antenna module 702 forms a third beam pattern B3 by means of the array antenna 720. With reference to FIGS. 9A, 9B, 9C, and 10, in the state in which the electronic device 600 is folded, the processor may control the first antenna module 701 so that the first antenna module 701 forms a second beam pattern B2 by means of the array antenna 720. In addition, in the state in which the electronic device 600 is folded, the processor may control the second antenna module 702 so that the second antenna module 702 forms a fourth beam pattern B4 by means of the array antenna 720.

According to various embodiments disclosed in the disclosure, optimal beam patterns of the antenna module 700 according to the relative position of the first housing 610 and the relative position of the second housing 620 may be stored in advance in the memory (e.g., the memory 130 in FIG. 1). In the embodiment, the processor may control the first antenna module 701 so that the first antenna module 701 forms the first beam pattern B1 having directionality capable of performing optimal communication with the external electronic device 600 in the state in which the electronic device 600 is unfolded. In addition, the processor may control the first antenna module 701 so that the first antenna module 701 forms the second beam pattern B2 having directionality capable of performing optimal communication with the external electronic device 600 in the state in which the electronic device 600 is folded. In the embodiment, the processor may control the second antenna module 702 so that the second antenna module 702 forms the third beam pattern B3 having directionality capable of performing optimal communication with the external electronic device 600 in the state in which the electronic device 600 is unfolded. In addition, the processor may control the second antenna module 702 so that the second antenna module 702 forms the fourth beam pattern B4 having directionality capable of performing optimal communication with the external electronic device 600 in the state in which the electronic device 600 is folded. Therefore, the processor may perform communication with the external electronic device 600 by controlling the directional beam pattern of the antenna module 700 on the basis of the folded or unfolded state of the electronic device 600.

According to various embodiments, the processor may control a communication signal of the antenna module 700 on the basis of the relative position of the first housing 610 and the relative position of the second housing 620. For example, the processor may control a communication signal of the antenna module 700 on the basis of a rotated state of the first housing 610 and a rotated state of the second housing 620. The processor may determine a relative position of the second housing 620 relative to the first housing 610 on the basis of a value measured by the sensor module (e.g., the sensor module 176 in FIG. 1). In the embodiment, the processor may receive information on an angle between the first housing 610 and the second housing 620 measured by an angle sensor (not illustrated) and determine a relative position of the second housing 620 relative to the first housing 610. In addition, the processor may determine a relative position of the second housing 620 relative to the first housing 610 by using a value measured by a gyro sensor (not illustrated). Further, the processor may determine a relative position of the second housing 620 relative to the first housing 610 in various ways. The processor may identify a communication signal of the antenna module 700 according to the relative position of the first housing 610 and the relative position of the second housing 620 stored in the memory on the basis of information on the relative position of the second housing 620 relative to the first housing 610 determined by using the sensor module. The processor may control the antenna module 700 so that a necessary communication signal is outputted in accordance with the relative position of the first housing 610 and the relative position of the second housing 620.

According to various embodiments, the processor may control a communication signal of the antenna module 700 on the basis of the unfolded or folded state of the electronic device 600. In the embodiment, a magnetic member (not illustrated) may be disposed on one of the first housing 610 and the second housing 620, and a Hall sensor (not illustrated) may be disposed on the remaining housing. The Hall sensor may determine the relative position of the second housing 620 relative to the first housing 610 by using a magnetic flux value detected as the first housing 610 and the second housing 620 move toward or away from each other. For example, the processor may identify whether the electronic device 600 is in the unfolded state or the folded state on the basis of the magnetic flux value detected by the Hall sensor. The processor may identify a communication signal of the antenna module 700 according to the state of the electronic device 600 stored in the memory on the basis of the state (e.g., the folded state or the unfolded state) of the electronic device 600 identified by the Hall sensor. Therefore, the processor may control the antenna module 700 so that a necessary communication signal is outputted in accordance with whether the electronic device 600 is in the unfolded state or the folded state. Further, the processor may control a communication signal of the antenna module 700 by identifying whether the electronic device 600 is in the unfolded state or the folded state by means of various sensors.

According to various embodiments, a width L1 (e.g., a length in the X-axis direction and/or a length in the Z-axis direction based on FIG. 8) of the radiation part 650 may be determined depending on a radiation width of the communication signal of the first antenna module 701. In the embodiment, as illustrated in FIGS. 9A, 9B, 9C, and 10, the width L1 of the radiation part 650 may be a width including a width W2 of the second beam pattern B2 of the first antenna module 701 in the folded state of the electronic device 600.

According to various embodiments, one area of the cover member 660, which faces the second antenna module 702, may be made of a nonmetallic material. A width L2 (e.g., a length in the X-axis direction and/or a length in the Z-axis direction based on FIG. 8) of the area of the cover member 660, which faces the second antenna module 702, may be determined depending on the radiation width of the second antenna module 702. In the embodiment, as illustrated in FIG. 8, the width L2 of the area of the cover member 660, which faces the second antenna module 702, may be a width including a width W3 of the third beam pattern B3 of the second antenna module 702 in the unfolded state of the electronic device 600. In addition, as illustrated in FIGS. 9A, 9B, 9C, and 10, the width L2 of the area of the cover member 660, which faces the second antenna module 702, may be a width including a width W4 of the fourth beam pattern B4 of the second antenna module 702 in the folded state of the electronic device 600.

According to various embodiments, as illustrated in FIG. 9B, some electric components positioned in a radiation direction of the communication signal of the first antenna module 701 may be removed. In the embodiment, in the folded state of the electronic device 600, the second housing 620 may include electric components (e.g., the second printed circuit board 840 and/or the second display panel) positioned in the radiation direction of the communication signal of the first antenna module 701. In this case, some of the electric components may be removed so that the communication signal of the first antenna module 701 is not degraded by the electric components disposed on the second housing 620. For example, a part of the second printed circuit board 840, which is disposed on the second housing 620, or a part of the second display panel 6402, which is disposed below the second window layer 6401 of the second display 640, may be removed. Therefore, the first antenna module 701 may mitigate or eliminate the degradation of the communication performance caused by the electric component disposed on the second housing 620 in the state in which the electronic device 600 is folded.

According to various embodiments, as illustrated in FIG. 9C, the electronic device 600 may include a lateral member 820 configured to surround the front surface and the rear surface of the electronic device 600. In the state in which the electronic device 600 is folded, at least a part of the lateral member 820 may be positioned in the radiation direction of the communication signal of the first antenna module 701. In this case, a part of the lateral member 820 positioned in the radiation direction of the communication signal of the first antenna module 701 may be made of a nonmetallic material 821 so that the communication signal of the first antenna module 701 is not degraded by the lateral member 820. In the embodiment, at least a part of an area of the lateral member 820, which corresponds to a radiation area of the first antenna module 701, may be made of the nonmetallic material 821. For example, a portion of the lateral member 820, which is positioned in the radiation direction of the communication signal of the first antenna module 701 in the state in which the electronic device 600 is folded may be made of the nonmetallic material 821, and the remaining portion may be made of a metallic material 822, thereby ensuring rigidity of the lateral member 820. Therefore, the first antenna module 701 may mitigate or eliminate the degradation of the communication performance caused by the lateral member 820 in the state in which the electronic device 600 is folded.

FIG. 10 is a view illustrating a state in which the first housing and the second housing are asymmetrically folded about the folding axis in electronic device illustrated in FIGS. 9A, 9B, and 9C according to an embodiment of the disclosure.

The electronic device 600 illustrated in FIG. 10 may be an embodiment in which the first housing 610 (e.g., the first housing 310 in FIG. 3A) and the second housing 620 (e.g., the second housing 620 in FIG. 3A) are asymmetrically folded about the folding axis P-P. In addition, the electronic device to be described below may not include the radiation part 650 described with reference to FIGS. 6A, 6B, 7, 8, 9A, 9B, and 9C.

Referring to FIG. 10, the first housing 610 and the second housing 620 may be asymmetrically folded about the folding axis P-P. In this case, the second housing 620 may not be positioned in the radiation direction of the communication signal generated by the first antenna module 701 in the state in which the electronic device 600 (e.g., the electronic device 101 in FIG. 1 or the electronic device 300 in FIG. 3A) is folded. For example, in the state in which the electronic device 600 is folded, the second housing 620 may not be positioned in the radiation area of the second beam pattern B2 of the first antenna module 701. Therefore, in the state in which the electronic device 600 is folded, the second housing 620, which is at least partially made of a conductive material, and the electric component, which is disposed on the second housing 620, are not positioned in the radiation area of the first antenna module 701, such that the communication performance of the first antenna module 701 may not be degraded. In addition, because the first housing 610 and the second housing 620 are asymmetrically folded about the folding axis P-P, the radiation part 650, which faces the first antenna module 701, may not be formed on the second housing 620.

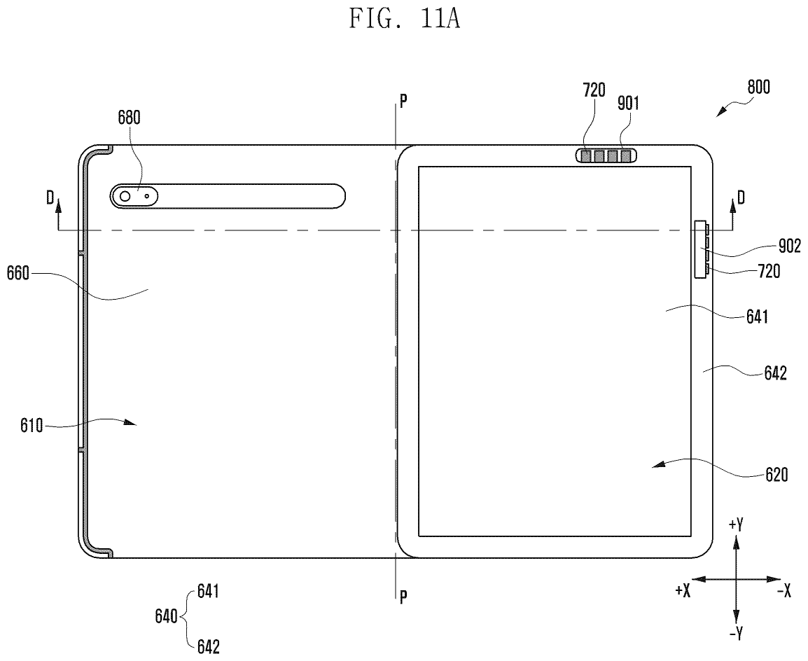

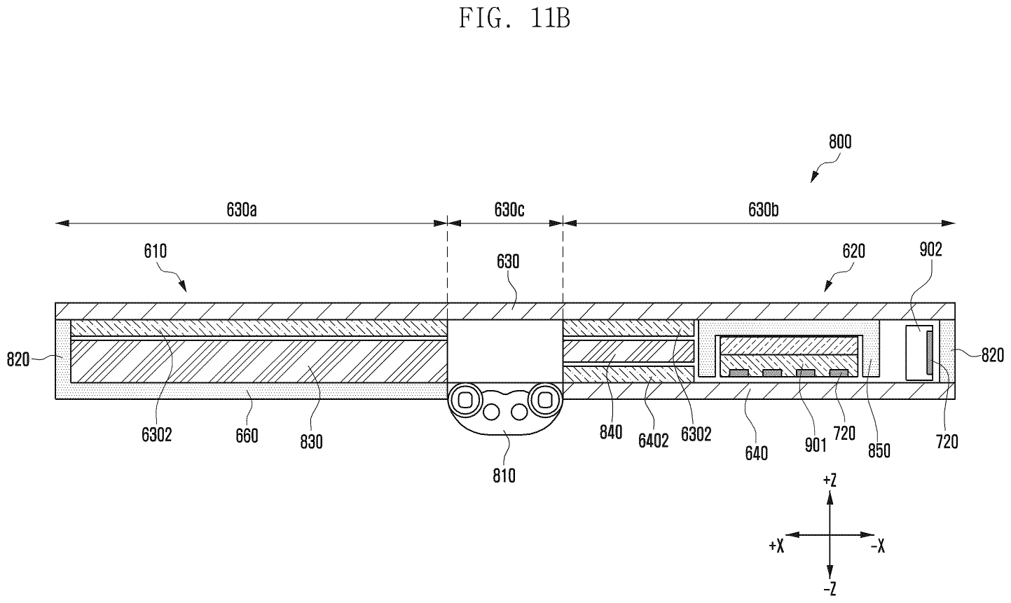

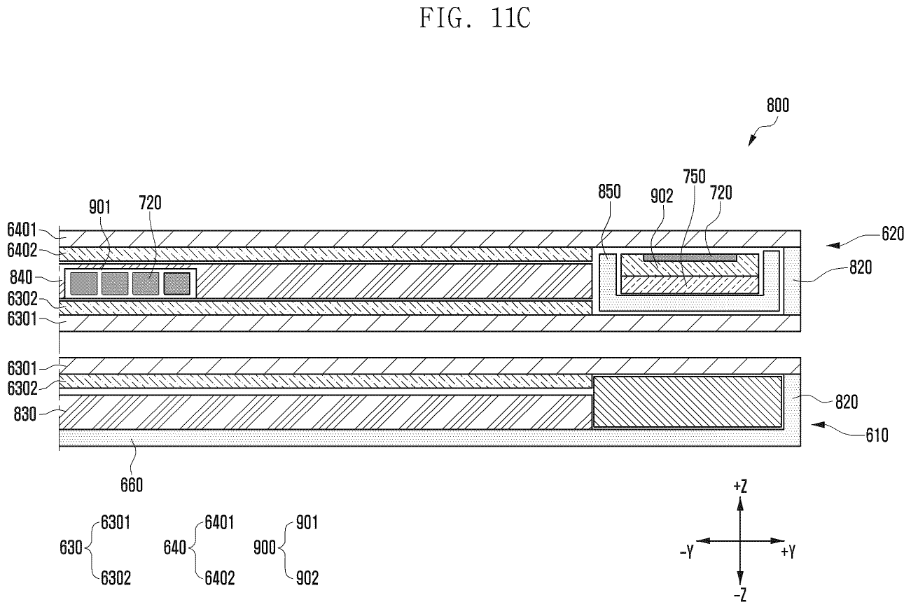

FIG. 11A is a view illustrating the rear surface of the electronic device in a state in which the electronic device illustrated in FIG. 6A and the electronic device are unfolded according to an embodiment of the disclosure.

FIG. 11B is a cross-sectional view of the electronic device taken along line D-D in FIG. 11A according to an embodiment of the disclosure.

FIG. 11C is a view illustrating a state in which the electronic device in FIGS. 11A and 11B is folded according to an embodiment of the disclosure.

Hereinafter, the electronic device (e.g., the electronic device 600 in FIG. 6A) described with reference to FIGS. 6A, 6B, 7, 8, 9A, 9B, and 9C and 10 and an electronic device 600 of another embodiment will be described. Because the electronic device 600 to be described below includes the constituent elements identical or similar to those of the electronic device 600 described above with reference to FIGS. 6A, 6B, 7, 8, 9A, 9B, 9C, and 10, the repeated detailed descriptions of the constituent elements will be omitted, and the same or similar constituent elements will be described by using the same reference numerals unless necessary. In addition, the electronic device to be described below may not include the radiation part 650 described with reference to FIGS. 6A, 6B, 7, 8, 9A, 9B, and 9C.

Referring to FIGS. 10A and 10B, an electronic device 800 (e.g., the electronic device 101 in FIG. 1, the electronic device 300 in FIG. 3A, or the electronic device 600 in FIG. 6A) according to various embodiments disclosed in the disclosure may include the first housing 610 (e.g., the first housing 310 in FIG. 3A) and the second housing 620 (e.g., the second housing 320 in FIG. 3A) connected to the hinge device 810 (e.g., the hinge device 420 (e.g., the hinge module) in FIG. 5) and configured to be rotatable about the folding axis P-P, the first display 630 (e.g., the first display 330 in FIG. 3A) disposed toward a front surface of the electronic device 800, the second display 640 (e.g., the second display 400 in FIG. 4A) disposed on a rear surface opposite to the front surface, and the cover member 660 configured to define an external appearance of the electronic device 800 and disposed toward the rear surface of the electronic device 800 The first display 630 may be a flexible display that may be at least partially deformed. For example, the first display 630 may include the first area 630a disposed on the first housing 610, the second area 630b disposed on the second housing 620, and the deformation area 630c positioned between the first area 630a and the second area 630b and configured to be deformed when the electronic device 800 is folded about the folding axis. The second display 640 may be disposed on one of the first housing 610 and the second housing 620 and directed toward the rear surface of the electronic device 800. The cover member 660 may be disposed on the remaining housing on which the second display 640 is not disposed. For example, with reference to FIG. 11A, the second display 640 may be disposed on the second housing 620 and directed toward the rear surface of the electronic device 800. In addition, the cover member 660 may be disposed on the first housing 610 and directed toward the rear surface of the electronic device 800. Hereinafter, for convenience of description, the description will be described on the premise that the cover member 660 is disposed on the first housing 610 and the second display 640 is disposed on the second housing 620.

According to various embodiments, as illustrated in FIGS. 11A and 11B, the electronic device 800 may include a plurality of antennas modules 900. The antenna module 900 may include a first antenna module 901 and a second antenna module 902. The first antenna module 901 may be disposed on the second housing 620 so that the communication signal may be radiated in a direction identical to a direction in which the second display 640 is directed. The first antenna module 901 may be disposed on the second housing 620 so that the array antenna 720 (e.g., the array antenna 720 in FIG. 7) faces the second display 640. For example, the first antenna module 901 may be disposed on the second housing 620 so as to face an opaque area (e.g., a BM area) 642 configured to surround a display area 641 of the second display 640. The second antenna module 902 may be disposed on one of the first housing 610 and the second housing 620 and directed toward the side surface that surrounds the front surface and the rear surface of the electronic device 800. For example, with reference to FIG. 11A, the second antenna module 902 may be disposed on the second housing 620 and directed toward the side surface of the electronic device 800. In any embodiment, the second antenna module 902 may be disposed on the first housing 610 and directed toward the side surface of the electronic device 800.

According to various embodiments, as illustrated in FIGS. 11B and 11C, the antenna module 900 may be disposed in the seating part 850. In the embodiment, the first antenna module 901 may be seated in the seating part 850 disposed in the second housing 620. The seating part 850 may include the partition wall 851 configured to surround the first antenna module 901, and the opening 852 configured to face the array antenna 720 of the first antenna module 901. Heat generated by an operation of the first antenna module 901 may be transferred to the seating part 850 made of a metallic material and/or a nonmetallic material. For example, the heat transfer material (e.g., the thermal interface material (TIM)) 750 may be disposed between the first antenna module 901 and the seating part 850. Heat generated from the first antenna module 901 may be transferred to the seating part 850 through the heat transfer material 750 and diffused to the surrounding. Therefore, because the amount of heat generation is reduced, the first antenna module 901 may maintain the communication performance at a predetermined level or higher.

In various embodiments, the antenna module 900 may be electrically connected to another printed circuit board (e.g., the first printed circuit board 830 (e.g., the substrate 370 in FIG. 5) or the second printed circuit board 840 (e.g., the substrate 370 in FIG. 5)) through a module interface. The module interface may include a connection member, e.g., a coaxial cable connector, a board-to-board connector, an interposer, or a flexible printed circuit board (FPCB). The RFIC 731 and/or the PMIC 732 of the antenna module 900 may be electrically connected to the printed circuit board through the connection member. In the embodiment, with reference to FIG. 11B, the first antenna module 901 and the second antenna module 902 may be disposed on the second housing 620 and electrically connected to the second printed circuit board 840 disposed on the second housing 620 through the connection member.

According to various embodiments disclosed in the disclosure, optimal beam patterns of the antenna module 900 according to the relative position of the first housing 610 and the relative position of the second housing 620 may be stored in advance in the memory (the memory 130 in FIG. 1). In the embodiment, the processor may control the first antenna module 901 so that the first antenna module 901 forms the first beam pattern having directionality capable of performing optimal communication with the external electronic device in the state in which the electronic device 800 is unfolded. In addition, the processor may control the first antenna module 901 so that the first antenna module 901 forms the second beam pattern having directionality capable of performing optimal communication with the external electronic device in the state in which the electronic device 800 is folded. In the embodiment, the processor may control the second antenna module 902 so that the second antenna module 902 forms the third beam pattern having directionality capable of performing optimal communication with the external electronic device in the state in which the electronic device 800 is unfolded. In addition, the processor may control the second antenna module 902 so that the second antenna module 902 forms the fourth beam pattern having directionality capable of performing optimal communication with the external electronic device in the state in which the electronic device is folded. Therefore, the processor may perform communication with the external electronic device by controlling the beam pattern of the antenna module 900 on the basis of the folded or unfolded state of the electronic device 800.

According to various embodiments, the processor may control a communication signal of the antenna module 900 on the basis of the relative position of the first housing 610 and the relative position of the second housing 620. For example, the processor may control a communication signal of the antenna module 900 on the basis of a rotated state of the first housing 610 and a rotated state of the second housing 620. The processor may determine a relative position of the second housing 620 relative to the first housing 610 on the basis of a value measured by the sensor module (e.g., the sensor module 176 in FIG. 1). In the embodiment, the processor may receive information on an angle between the first housing 610 and the second housing 620 measured by the angle sensor and determine a relative position of the second housing 620 relative to the first housing 610. In addition, the processor may determine a relative position of the second housing 620 relative to the first housing 610 by using a value measured by the gyro sensor. Further, the processor may determine a relative position of the second housing 620 relative to the first housing 610 in various ways. The processor may identify a communication signal of the antenna module 900 according to the relative position of the first housing 610 and the relative position of the second housing 620 stored in the memory on the basis of information on the relative position of the second housing 620 relative to the first housing 610 determined by using the sensor module. The processor may control the antenna module 900 so that a necessary communication signal is outputted in accordance with the relative position of the first housing 610 and the relative position of the second housing 620.

According to various embodiments, the processor may control a communication signal of the antenna module 900 on the basis of the unfolded state of the electronic device 800 (e.g., the unfolded state of the electronic device 800 illustrated in FIG. 11B) or the folded state (e.g., the folded state of the electronic device 800 illustrated in FIG. 11C). In the embodiment, a magnetic member may be disposed on one of the first housing 610 and the second housing 620, and a Hall sensor may be disposed on the remaining housing. The Hall sensor may determine the relative position of the second housing 620 relative to the first housing 610 by using a magnetic flux value detected as the first housing 610 and the second housing 620 move toward or away from each other. For example, the processor may identify whether the electronic device 800 is in the unfolded state or the folded state on the basis of the magnetic flux value detected by the Hall sensor. The processor may identify a communication signal of the antenna module 900 according to the state of the electronic device 800 stored in the memory on the basis of the state (e.g., the folded state or the unfolded state) of the electronic device 800 identified by the Hall sensor. Therefore, the processor may control the antenna module 900 so that a necessary communication signal is outputted in accordance with whether the electronic device 800 is in the unfolded state or the folded state. Further, the processor may control the antenna module 900 by identifying whether the electronic device 800 is in the unfolded state or the folded state by means of various sensors so that a necessary communication signal is outputted.

The electronic device 600 (e.g., the electronic device 101 in FIG. 1 or the electronic device 300 in FIG. 3A) according to various embodiments disclosed in the disclosure may include the first housing 610 (e.g., the first housing 310 in FIG. 3A), the second housing 620 (e.g., the second housing 320 in FIG. 3A) rotatably connected to the first housing, the display (e.g., the first display 630 in FIG. 6A or the first display 330 in FIG. 3A) disposed on the front surface of the electronic device and having a partial area configured to be deformed by the rotation of the second housing relative to the first housing, the first antenna module 701 disposed on one of the first housing and the second housing so that the communication signal is radiated in the direction identical to the direction in which the display faces the outside of the electronic device, and the radiation part 650 included in the other of the first housing and the second housing and including the internal space 651 facing the first antenna module in the state in which the electronic device is folded so that the first housing and the second housing face each other, in which the first antenna module may transmit or receive the communication signal in the designated frequency band through the radiation part.

In addition, the electronic device may further include the processor 120 electrically connected to the first antenna module, and the processor may control the communication signal of the first antenna module at least on the basis of the rotated state of the first housing and the rotated state of the second housing.

In addition, the electronic device may further include the memory 130 electrically connected to the processor, and the sensor module (e.g., the sensor module 176 in FIG. 1) electrically connected to the processor and configured to measure the relative position of the second housing relative to the first housing, and the processor may identify information on the relative position of the second housing relative to the first housing at least on the basis of the value measured by the sensor module, identify the communication signal of the first antenna module predetermined at least on the basis of information on the position of the second housing relative to the first housing stored in the memory and corresponding to information on the identified relative position, and control the first antenna module so that the identified communication signal is outputted.

In addition, the electronic device may further include the magnetic member disposed on one of the first housing and the second housing, the Hall sensor disposed on the other of the first housing and the second housing so as to face the magnetic member, and the processor electrically connected to the first antenna module and the Hall sensor, and the processor may determine the relative position of the second housing related to the first housing by using the magnetic flux value detected by the Hall sensor and control the communication signal of the first antenna module at least on the basis of the determined relative position.

In addition, the electronic device may further include the processor 120 electrically connected to the first antenna module, the processor may control the first antenna module to form the first beam pattern B1 in the unfolded state of the electronic device (e.g., the unfolded state of the electronic device 600 in FIG. 8) in which one surface of the first housing and one surface of the second housing are directed in the same direction, and the processor may control the first antenna module to form the second beam pattern B2 in the state in which the electronic device is folded so that the first housing and the second housing face each other.

In addition, the injection-molded product made of a nonmetallic material may be disposed in the radiation part.

In addition, the electronic device may further include the cover member 660 disposed on at least one of the first housing and the second housing, directed toward the rear surface of the electronic device, and configured to define the external appearance of the electronic device, and the second antenna module 702 disposed on at least one of the first housing and the second housing so that the communication signal is radiated in the direction identical to the direction in which the cover member faces the outside of the electronic device.

In addition, one area 661 of the cover member, which faces the second antenna module, may be made of a nonmetallic material.

In addition, the width L1 of the radiation part may be determined depending on the radiation width W2 of the communication signal of the first antenna module.

In addition, the width L1 of the radiation part may be the width including the radiation width W2 of the communication signal of the first antenna module.

In addition, the display may include the display area 631 configured to display a screen, and the opaque area 632 configured to surround the display area, and the first antenna module may be disposed on one of the first housing and the second housing while corresponding to the opaque area.

In addition, the electronic device may include the lateral member 820 configured to surround the front surface and the rear surface of the electronic device, and at least a part of the area of the lateral member, which corresponds to the radiation area of the first antenna module, may be made of the nonmetallic material 821.

In addition, one of the first housing and the second housing may have the seating part 850 in which the first antenna module is disposed, and the seating part 850 may include the partition wall 851 configured to surround the first antenna module.

In addition, the electronic device may further include the heat transfer material 750 disposed between the first antenna module and the seating part.

In addition, the first antenna module may transmit or receive the radio wave in the mmWave band.

The electronic device 800 (e.g., the electronic device 101 in FIG. 1 or the electronic device 300 in FIG. 3A) according to various embodiments disclosed in the disclosure may include the first housing 610 (e.g., the first housing 310 in FIG. 3A), the second housing 620 (e.g., the second housing 320 in FIG. 3A) rotatably connected to the first housing, the first display 630 (e.g., the first display 330 in FIG. 3A) disposed on the first housing and the second housing so as to be directed toward the front surface of the electronic device and having a partial area configured to be deformed by the rotation of the second housing relative to the first housing, the second display 640 (e.g., the second display 400 in FIG. 3B) disposed on one of the first housing and the second housing so as to be directed toward the rear surface of the electronic device, the first antenna module 901 disposed on the second housing so that the communication signal is radiated in the direction identical to the direction in which the second display faces the outside of the electronic device, the second antenna module 902 positioned on the side surface that surrounds the front surface and the rear surface of the electronic device, the second antenna module 902 being disposed on one of the first housing and the second housing, and the processor 120 electrically connected to the first antenna module and the second antenna module, and the processor may control the communication signals of the first and second antenna modules at least on the basis of the rotated state of the first housing and the rotated state of the second housing.

In addition, the electronic device may further include the memory 130 electrically connected to the processor, and the sensor module (e.g., the sensor module 176 in FIG. 1) electrically connected to the processor and configured to measure the relative position of the second housing relative to the first housing, and the processor may identify information on the relative position of the second housing relative to the first housing at least on the basis of the value measured by the sensor module, identify the communication signals of the first and second antenna modules predetermined at least on the basis of information on the position of the second housing relative to the first housing stored in the memory and corresponding to information on the identified relative position, and control the first and second antenna modules so that the identified communication signals are outputted.

In addition, the electronic device may further include the magnetic member disposed on one of the first housing and the second housing, and the Hall sensor disposed on the other of the first housing and the second housing so as to face the magnetic member and electrically connected to the processor, and the processor may determine the relative position of the second housing relative to the first housing by using the magnetic flux value detected by the Hall sensor and control the communication signals of the first and second antenna modules at least on the basis of the determined relative position.

In addition, the processor may control the first antenna module to form the first beam pattern in the unfolded state of the electronic device (e.g., the unfolded state of the electronic device 800 in FIG. 11B) in which one surface of the first housing and one surface of the second housing are directed in the same direction, and the processor may control the first antenna module to form the second beam pattern in the state in which the electronic device is folded so that the first housing and the second housing face each other.

In addition, the second display may include the display area 641 configured to display a screen, and the opaque area 642 configured to surround the display area, and the first antenna module may be disposed on one of the first housing and the second housing while corresponding to the opaque area.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a first housing;
a second housing rotatably connected to the first housing;
a display disposed on a front surface of the electronic device and having a partial area configured to be deformed by a rotation of the second housing relative to the first housing;
a first antenna module disposed on one of the first housing and the second housing so that a communication signal is radiated in a direction identical to a direction in which the display faces the outside of the electronic device; and
a radiation part included in the other of the first housing and the second housing and comprising an internal space that faces the first antenna module in a state in which the electronic device is folded so that the first housing and the second housing face each other,
wherein the first antenna module transmits or receives the communication signal in a designated frequency band through the radiation part.

2. The electronic device of claim 1, further comprising:
memory storing one or more computer programs; and
one or more processors communicatively coupled to the first antenna module, and the memory,
wherein the one or more computer programs include computer-executable instructions that, when executed by the one or more processors individually or collectively, cause the electronic device to:
control the communication signal of the first antenna module at least on the basis of a rotated state of the first housing and a rotated state of the second housing.

3. The electronic device of claim 2, further comprising:
a sensor module communicatively coupled to the one or more processors and configured to measure a relative position of the second housing relative to the first housing,
wherein the one or more computer programs further include computer-executable instructions that, when executed by the one or more processors individually or collectively, cause the electronic device to:
identify information on the relative position of the second housing relative to the first housing at least on the basis of a value measured by the sensor module,
identify the communication signal of the first antenna module predetermined at least on the basis of information on a position of the second housing relative to the first housing stored in the memory and corresponding to information on the identified relative position, and
control the first antenna module so that the identified communication signal is outputted.

4. The electronic device of claim 1, further comprising:
a magnetic member disposed on one of the first housing and the second housing;
a Hall sensor disposed on the other of the first housing and the second housing so as to face the magnetic member;
memory storing one or more computer programs; and
one or more processors communicatively coupled to the first antenna module, the Hall sensor and the memory,
wherein the one or more computer programs include computer-executable instructions that, when executed by the one or more processors individually or collectively, cause the electronic device to:
determine a relative position of the second housing relative to the first housing by using a magnetic flux value detected by the Hall sensor, and
control the communication signal of the first antenna module at least on the basis of the determined relative position.

5. The electronic device of claim 1, further comprising:
memory storing one or more computer programs; and
one or more processors communicatively coupled to the first antenna module, and the memory,
wherein the one or more computer programs further include computer-executable instructions that, when executed by the one or more processors individually or collectively, cause the electronic device to:
control the first antenna module to form a first beam pattern in an unfolded state of the electronic device in which one surface of the first housing and one surface of the second housing are directed in the same direction, and
control the first antenna module to form a second beam pattern in the state in which the electronic device is folded so that the first housing and the second housing face each other.

6. The electronic device of claim 1, further comprising:
an injection-molded product made of a nonmetallic material,
wherein the injection-molded product made of the nonmetallic material is disposed in the radiation part.

7. The electronic device of claim 1, further comprising:
a cover member disposed on at least one of the first housing and the second housing so as to face a rear surface of the electronic device and configured to define an external appearance of the electronic device; and
a second antenna module disposed on at least one of the first housing and the second housing so that the communication signal is radiated in the direction identical to the direction in which the cover member faces the outside of the electronic device,
wherein one area of the cover member, which faces the second antenna module, is made of a nonmetallic material.

8. The electronic device of claim 1, wherein the radiation part having a width that includes a radiation width of the communication signal of the first antenna module.

9. The electronic device of claim 1,
wherein the display comprises:
a display area configured to display a screen, and
an opaque area configured to surround the display area, and
wherein the first antenna module is disposed on one of the first housing and the second housing while corresponding to the opaque area.

10. The electronic device of claim 1,
wherein the electronic device comprises a lateral member configured to surround the front surface and a rear surface of the electronic device, and
wherein at least a part of an area of the lateral member, which corresponds to a radiation area of the first antenna module, is made of a nonmetallic material.

11. The electronic device of claim 1,
wherein one of the first housing and the second housing has a seating part in which the first antenna module is disposed, and
wherein the seating part comprises a partition wall configured to surround the first antenna module.

12. An electronic device comprising:
a first housing;
a second housing rotatably connected to the first housing;
a first display disposed on the first housing and the second housing so as to face a front surface of the electronic device and having a partial area configured to be deformed by a rotation of the second housing relative to the first housing;
a second display disposed on one of the first housing and the second housing so as to be directed toward a rear surface of the electronic device;
a first antenna module disposed on the second housing so that a communication signal is radiated in a direction identical to a direction in which the second display faces the outside of the electronic device;
a second antenna module positioned on a side surface that surrounds the front surface and the rear surface of the electronic device, the second antenna module being disposed on one of the first housing and the second housing;
memory storing one or more computer programs; and
one or more processors communicatively coupled to the first antenna module, the second antenna module, and the memory,
wherein the one or more computer programs include computer-executable instructions that, when executed by the one or more processors individually or collectively, cause the electronic device to:
control communication signals of the first and second antenna modules at least on the basis of a rotated state of the first housing and a rotated state of the second housing.

13. The electronic device of claim 12, further comprising:
a sensor module communicatively coupled to the one or more processors and configured to measure a relative position of the second housing relative to the first housing,
wherein the one or more computer programs further include computer-executable instructions that, when executed by the one or more processors individually or collectively, cause the electronic device to:
identify information on the relative position of the second housing relative to the first housing at least on the basis of a value measured by the sensor module,
identify the communication signals of the first and second antenna modules predetermined at least on the basis of information on a position of the second housing relative to the first housing stored in the memory and corresponding to information on the identified relative position, and
control the first antenna module and the second antenna module so that the identified communication signals are outputted.

14. The electronic device of claim 12, further comprising:
a magnetic member disposed on one of the first housing and the second housing; and
a Hall sensor disposed on the other of the first housing and the second housing so as to face the magnetic member and communicatively coupled to the one or more processors,
wherein the one or more computer programs further include computer-executable instructions that, when executed by the one or more processors individually or collectively, cause the electronic device to:
determine a relative position of the second housing relative to the first housing by using a magnetic flux value detected by the Hall sensor, and
control the communication signals of the first and second antenna modules at least on the basis of the determined relative position.

15. The electronic device of claim 12, wherein the one or more computer programs further include computer-executable instructions that, when executed by the one or more processors individually or collectively, cause the electronic device to:
control the first antenna module to form a first beam pattern in an unfolded state of the electronic device in which one surface of the first housing and one surface of the second housing are directed in the same direction, and
control the first antenna module to form a second beam pattern in a state in which the electronic device is folded so that the first housing and the second housing face each other.
